(19) United States
(12) Patent Application Publication
(10) Pub. No.: US 2023/0348311 A1
(43) Pub. Date: Nov. 2, 2023

(54) ADDITIVE MANUFACTURING OF SILICON COMPONENTS

(71) Applicants: LAM RESEARCH CORPORATION, Fremont, CA (US); SILFEX, INC., Eaton, OH (US)

(72) Inventors: Seyedalireza TORBATISARRAF, San Jose, CA (US); Abhinav Shekhar RAO, Cambridge, MA (US); Jihong CHEN, Cincinnati, OH (US); Yi SONG, Cincinnati, OH (US); Jerome HUBACEK, Fremont, CA (US); Vijay NITHIANANTHAN, Springboro, OH (US)

(21) Appl. No.: 17/923,155

(22) PCT Filed: Apr. 26, 2021
(86) PCT No.: PCT/US2021/029053

§ 371 Date: Nov. 3, 2022

Related U.S. Application Data
(60) Provisional application No. 63/128,925, filed on Dec. 22, 2020.
(60) Provisional application No. 63/021,528, filed on May 7, 2020.

(51) Int. Cl. C03B 19/01; B33Y 70/00; B33Y 10/00; B33Y 30/00

(52) U.S. Cl. CPC C03B 19/01; B33Y 70/00; B33Y 10/00; B33Y 30/00

(57) ABSTRACT

A method of performing 3D printing of a silicon component includes adding powdered silicon to a 3D printing tool. For each the powdered silicon, forming a layer of the powder bed to a pre-determined thickness, directing a high-powered beam in a pre-determined pattern into the powder-bed to melt the powdered silicon. After no further layers are needed, the silicon component is cooled at a pre-determined temperature ramp-down rate. In a fully dense printing method, buffer layers of silicon are initially printed on a steel substrate, and then layers of silicon for the actual component are printed on top of the buffer layers using a double printing method. In a fully dense and crack free printing method, one or more heaters and thermal insulation are used to minimize temperature gradient during Si printing, in-situ annealing, and cooling.

### CROSS-REFERENCE TO RELATED APPLICATIONS

This application claims the benefit of U.S. Provisional Application No. 63/021,528, filed on May 7, 2020 and U.S. Provisional Application No. 63/128,925, filed on Dec. 22, 2020. The entire disclosures of the applications referenced above are incorporated herein by reference.

### FIELD

The present disclosure relates generally to manufacturing silicon components and more particularly to 3D printing of fully dense and crack free silicon using electron beam melting.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, a plasma enhanced chemical vapor deposition (PECVD) process, a chemically enhanced plasma vapor deposition (CEPVD) process, and a sputtering physical vapor deposition (PVD) process. Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal, an electrostatic chuck (ESC), and so on in a processing chamber of the substrate processing system. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. A computer-controlled robot typically transfers substrates from one processing chamber to another in a sequence in which the substrates are to be processed.

Various types of components, such as components for semiconductor processing chamber applications, currently use subtractive-machining methods to remove silicon from a larger block of silicon to make components. One problem encountered when using subtractive-machining methods however is that it is difficult or impossible to make parts with complex features, such as gas plenum, curved gas holes, or entire monolithic-silicon process chambers (such chambers are typically formed as three or more pieces and then later assembled into a whole chamber). Another problem of the subtractive-machining methods used currently is that materials utilization is poor since frequently extremely large portions of the larger block of silicon to make components must be removed, and frequently wasted, to make the machined components.

Other technologies recently attempted have focused on additive-manufacturing techniques using silicon. However, these attempts have produced silicon components with residual stress and induced cracks. The cracks in the silicon weaken the structure of the manufactured components.

The information described in this section is provided to offer the skilled artisan a context for the following disclosed subject matter and should not be considered as admitted prior art.

### SUMMARY

In one exemplary embodiment, the disclosed subject matter describes a method of performing three-dimensional (3D) printing of a silicon component, the method including adding powdered silicon to a 3D printing tool. For each layer of the 3D printing in a layer-by-layer process: forming a powder bed of the powdered silicon in the 3D printing tool, baking the powdered silicon in a temperature range of 650° C. to 750° C. under a high-vacuum condition in a range of 10⁻⁵ Torr to 10⁻⁷ Torr to decompose and remove surface oxides from the powdered silicon, forming a layer of the powder bed to a pre-determined thickness, directing a high-powered beam under the high-vacuum condition in a pre-determined pattern into the formed powder-bed, the high-powered beam having sufficient energy to melt the powdered silicon, and making a determination as to whether additional layers in the 3D printing are needed. Based on a determination that no additional layers are needed, cooling the silicon component at a pre-determined temperature ramp-down rate to about ambient temperature of an environment in which the 3D printing tool is located.

In another exemplary embodiment, the disclosed subject matter describes a method of performing three-dimensional (3D) printing of a silicon component, the method including loading a design file into a 3D printing tool where the design file containing geometries of the silicon component including coordinates for each of multiple layers to print the silicon component. For each layer of the 3D printing of the silicon component: forming a powder bed of powdered silicon in the 3D printing tool, baking the powdered silicon in a temperature range of 650° C. to 750° C. under a high-vacuum condition in a range of 10⁻⁵ Torr to 10⁻⁷ Torr to decompose and remove surface oxides from the powdered silicon, raking a layer of the powder bed to a pre-determined thickness, directing an electron beam under the high-vacuum condition in a pre-determined pattern into the raked powdered-bed, the pre-determined pattern being based on the design file, the electron beam having sufficient energy to melt the powdered silicon, and making a determination as to whether additional layers in the 3D printing are needed. Based on a determination that no additional layers are needed, cooling the silicon component at a pre-determined temperature to about ambient temperature in which the 3D printing tool is located.

Various systems and apparatuses for performing the exemplary methods, as well as other methods, are described in detail herein.

A system for printing a fully dense component of a nonmetallic material, the system comprises a chamber under vacuum. A first vertically movable plate is arranged in the chamber to support a substrate. A second vertically movable plate is arranged adjacent to the first vertically movable plate. The second vertically movable plate is configured to store a powder of the nonmetallic material and to dose the substrate with the powder prior to printing each layer of the nonmetallic material. An electron beam generator is configured to supply an electron beam. A controller is configured to print a plurality of layers of the nonmetallic material on the substrate using the electron beam and to print a layer of the nonmetallic material on the plurality of layers to build the component on the plurality of layers by: printing a first sublayer of the layer of the nonmetallic material using the electron beam having a first power and a first speed and by printing a second sublayer of the layer of the nonmetallic material on the first sublayer using the electron beam having a second power and a second speed. The first speed is greater than the second speed. The first power is less than the second power.

In another feature, the nonmetallic material comprises particles having a diameter within a range of 40-100 μm.

In other features, the controller is further configured to print the first sublayer using the electron beam having a first orientation and to print the second sublayer using the electron beam having a second orientation that is different than the first orientation.

In another feature, the nonmetallic material is selected from a group consisting of silicon, silicon carbide, alumina, and ceramics.

In other features, the system further comprises one or more meshes having holes of different diameters and a vibrating system configured to vibrate the one or more meshes. The powder is selected from a stock by passing the stock through the one or more meshes. The selected powder comprises particles having a diameter within a range of 40-100 μm.

In another feature, the system further comprises a plate movement assembly configured to move the first vertically movable plate in a downward direction after printing each layer and to move the second vertically movable plate in an upward direction after printing each layer.

In still other features, a method of printing a fully dense component of a nonmetallic material on a substrate comprises printing a plurality of layers of the nonmetallic material on the substrate using an electron beam. The method further comprises printing a layer of the nonmetallic material on the plurality of layers to build the component on the plurality of layers by: printing a first sublayer of the layer of the nonmetallic material using the electron beam having a first power and a first speed and by printing a second sublayer of the layer of the nonmetallic material on the first sublayer using the electron beam having a second power and a second speed. The first speed is greater than the second speed. The first power is less than the second power.

In another feature, the nonmetallic material comprises particles having a diameter within a range of 40-100 μm.

In other features, the method further comprises printing the first sublayer using the electron beam having a first orientation and printing the second sublayer using the electron beam having a second orientation that is different than the first orientation.

In another feature, the nonmetallic material is selected from a group consisting of silicon, silicon carbide, alumina, and ceramics.

In another feature, the method further comprises supplying a dose of a powder of the nonmetallic material before printing each layer. The powder comprises particles having a diameter within a range of 40-100 μm.

In another feature, the method further comprises selecting the powder from a stock by passing the stock through one or more meshes having holes of different diameters and by vibrating the one or more meshes.

In another feature, the method further comprises printing the component in a chamber under vacuum.

In still other features, a method of printing a component of a nonmetallic material on a substrate comprises printing a plurality of layers of the nonmetallic material on the substrate using an electron beam. The plurality of layers form a base on which to build the component. The method further comprises building the component on the plurality of layers by printing one or more layers of the nonmetallic material on the plurality of layers using the electron beam.

In another feature, the nonmetallic material comprises particles having a diameter within a range of 40-100 μm.

In other features, printing each layer of the one or more layers comprises printing a first sublayer of the nonmetallic material using the electron beam having a first power and a first speed and printing a second sublayer of the nonmetallic material on the first sublayer using the electron beam having a second power and a second speed. The first speed is greater than the second speed. The first power is less than the second power.

In other features, the method further comprises printing the first sublayer using the electron beam having a first orientation and printing the second sublayer using the electron beam having a second orientation that is different than the first orientation.

In another feature, the nonmetallic material is selected from a group consisting of silicon, silicon carbide, alumina, and ceramics.

In other features, the method further comprises supplying a dose of a powder of the nonmetallic material before printing each layer. The powder comprises particles having a diameter within a range of 40-100 μm.

In another feature, the method further comprises selecting the powder from a stock by passing the stock through one or more meshes having holes of different diameters and by vibrating the one or more meshes.

In still other features, a method of printing a fully dense component of a nonmetallic material on a substrate comprises printing a first sublayer of a layer of the nonmetallic material on the substrate using an electron beam having a first power and a first speed. The method further comprises printing a second sublayer of the layer of the nonmetallic material on the first sublayer using the electron beam having a second power and a second speed. The first speed is greater than the second speed. The first power is less than the second power.

In another feature, the nonmetallic material comprises particles having a diameter within a range of 40-100 μm.

In other features, the method further comprises printing the first sublayer using the electron beam having a first orientation and printing the second sublayer using the electron beam having a second orientation that is different than the first orientation.

In another feature, the method further comprises printing a plurality of layers of the nonmetallic material on the substrate using the electron beam prior to printing the layer.

In another feature, the plurality of layers form a base on which the component is built by printing the layer.

In another feature, the nonmetallic material is selected from a group consisting of silicon, silicon carbide, alumina, and ceramics.

In another feature, the method further comprises supplying a dose of a powder of the nonmetallic material before printing each layer. The powder comprises particles having a diameter within a range of 40-100 μm.

In another feature, the method further comprises selecting the powder from a stock by passing the stock through one or more meshes having holes of different diameters and by vibrating the one or more meshes.

In still other features, a system for printing a fully dense and crack free component of a nonmetallic material on a substrate made of the nonmetallic material comprises a chamber for printing the fully dense and crack free component, the chamber being thermally insulated. The system further comprises a first vertically movable plate arranged in the chamber to support the substrate and a thermally insulating material arranged on a top surface of the first vertically movable plate and under the substrate. The system further comprises a heater configured to heat the substrate and a region of the chamber surrounding the substrate prior to printing the component on the substrate. The system further comprises a powder feeder configured to supply a powder of the nonmetallic material and an electron generator configured to supply an electron beam to print a layer of the nonmetallic material on the substrate while the heater continues to heat the substrate and the region of the chamber surrounding the substrate during the printing.

In another feature, the powder comprises particles having a diameter within a range of 40-100 μm.

In another feature, the heater is configured to heat the substrate and the region of the chamber surrounding the substrate to a temperature greater than a ductile to brittle transition temperature of the nonmetallic material during the printing of the component.

In another feature, after the printing, the heater is configured to continue heating the substrate and the region of the chamber surrounding the substrate while annealing the component in the chamber.

In another feature, after the printing, the component remains surrounded by the powder while the component slowly cools at a controlled rate.

In another feature, the chamber is thermally insulated with one or more of layers of one or more insulating materials.

In another feature, the nonmetallic material is selected from a group consisting of silicon, silicon carbide, alumina, and ceramics.

In another feature, the heater is arranged under the substrate or surrounding the substrate and the region of the chamber above the substrate.

In other features, the powder feeder comprises a second vertically movable plate arranged adjacent to the first vertically movable plate, and the second vertically movable plate is configured to store the powder and to dose the substrate with the powder prior to printing each layer of the nonmetallic material.

In another feature, the system further comprises a plate movement assembly configured to move the first vertically movable plate in a downward direction after printing each layer and to move the second vertically movable plate in an upward direction after printing each layer.

In another feature, the system further comprises one or more additional heaters configured to heat a region of the chamber above the substrate during the printing of the component.

In another feature, the chamber is under vacuum.

In other features, the system further comprises one or more meshes having holes of different diameters and a vibrating system configured to vibrate the one or more meshes. The powder is selected from a stock by passing the stock through the one or more meshes. The selected powder comprises particles having a diameter within a range of 40-100 μm.

In still other features, a method of printing a fully dense and crack free component of a nonmetallic material on a substrate made of the nonmetallic material in a chamber comprises heating the substrate and a region of the chamber surrounding the substrate prior to printing a layer of the nonmetallic material on the substrate. The method further comprises printing the layer of the nonmetallic material on the substrate using an electron beam while continuing to heat the substrate and the region of the chamber surrounding the substrate during the printing.

In another feature, the nonmetallic material comprises particles having a diameter within a range of 40-100 μm.

In another feature, the method further comprises heating the substrate and the region of the chamber surrounding the substrate to a temperature greater than a ductile to brittle transition temperature of the nonmetallic material during the printing of the component.

In another feature, the method further comprises after the printing, annealing and slow cooling the component in the chamber while continuing to heat the substrate and the region of the chamber surrounding the substrate.

In another feature, the method further comprises after the printing, cooling the component by surrounding the component with a powder of the nonmetallic material.

In another feature, the method further comprises thermally insulating the chamber using one or more of layers of one or more insulating materials.

In another feature, the nonmetallic material is selected from a group consisting of silicon, silicon carbide, alumina, and ceramics.

In other features, the method further comprises dosing the substrate with the nonmetallic material prior to printing each layer of the layer of the nonmetallic material, and supplying the electron beam subsequent to the dosing to print each layer of the nonmetallic material.

In another feature, the method further comprises heating a region of the chamber above the substrate during the printing of the component.

In another feature, the method further comprises maintaining vacuum in the chamber.

In another feature, the method further comprises maintaining a vacuum in the chamber.

In other features, the method further comprises selecting a powder of the nonmetallic material from a stock by passing the stock through one or more meshes having holes of different diameters and by vibrating the one or more meshes. The selected powder comprises particles having a diameter within a range of 40-100 μm.

In still other features, a system comprises a chamber including an upper portion having an inlet to receive silicon powder, a carrier gas, and a dopant; a middle portion connected to the upper portion; and a third portion connected to the middle portion and having an outlet. The system comprises a coil arranged around the upper portion and a power supply configured to supply power to the coil. The system comprises a controller configured to control supply of the silicon powder, the carrier gas, and the dopant to the inlet and to control the power supplied to the coil to generate plasma. The outlet outputs a spherical shaped, dense, and doped silicon powder.

In other features, the middle portion has a greater cross-sectional area than the upper portion. The third portion has a smaller cross-sectional area than the upper portion.

In other features, the upper portion includes an inner tube, a middle tube coaxially surrounding the inner tube, and an outer tube defined by an outer wall of the middle tube and an inner wall of the upper portion. The inner, middle, and the outer tubes extend vertically downwards from a top end of the upper portion to a midpoint of the upper portion. The coil is arranged around the upper portion between the midpoint of the upper portion and a bottom end of the upper portion.

In other features, the silicon powder is supplied to the inner tube, and the system further comprises a first gas source to supply the carrier gas to mix with the silicon powder, a second gas source to supply the dopant to the middle tube, and a third gas source to supply a sheath gas to the outer tube.

In still other features, a method of building a component for a substrate processing system comprises arranging first and second subcomponents of the component in a thermally insulated zone in a chamber under vacuum and heating the first and second subcomponents in the thermally insulated zone to a predetermined temperature. The method comprises bonding a first end of the first subcomponent to a second end of the second subcomponent by partially melting material at the first and second ends using an electron beam followed by solidifying the melted material. The method comprises annealing the bonded first and second subcomponents to form the component, cooling the formed component to a first temperature at a first rate, and cooling the formed component to a second temperature at a second rate. The second temperature is less than the first temperature. The first rate is slower than the second rate.

In another feature, the component is made of a nonmetallic material selected from a group consisting of silicon, silicon carbide, alumina, and ceramics.

In another feature, the method further comprises bonding the first and second subcomponents without using any additional material.

In another feature, the method further comprises cleaning mating surfaces of the first and second ends before the melting.

In another feature, the method further comprises grinding excess material from the component and cleaning the component.

In still other features, a method of repairing a component used in a substrate processing system comprises arranging the component in a thermally insulated zone in a chamber under vacuum, adding a powdered material to a defective region of the component, heating the component in the thermally insulated zone to a predetermined temperature, and melting the powdered material and a portion of the defective region of the component using an electron beam to form a melt pool. The method comprises reducing a power of the electron beam to let the melted pool to solidify, annealing the component, cooling the component to a first temperature at a first rate, and cooling the component to a second temperature at a second rate. The second temperature is less than the first temperature. The first rate is slower than the second rate.

In other features, the component is made of a nonmetallic material selected from a group consisting of silicon, silicon carbide, alumina, and ceramics. The powdered material is the same nonmetallic material of which the component is made of.

In another feature, the method further comprises grinding excess material around the defective region of the component and cleaning the component.

In still other features, a system for building a component of a substrate processing system comprises a chamber under vacuum and a pedestal arranged in the chamber to support first and second subcomponents of the component thereon. The system comprises a heater arranged in the chamber proximate to the pedestal, and a thermal insulator arranged in the chamber forming a thermally insulated zone around the pedestal and the heater. The system comprises an electron beam generator arranged in the chamber to direct an electron beam onto ends of the first and second subcomponents through an opening in the thermally insulated zone to bond the ends together to form the component.

In other features, the system further comprises a first actuator configured to rotate the pedestal around a first axis, and a second actuator configured to move the electron beam generator along a second axis that is perpendicular to the first axis.

In another feature, the system further comprises a controller configured to control the heater to heat the first and second subcomponents to a predetermined temperature, and to control the electron beam generator to direct the electron beam onto the ends of the heated first and second subcomponents.

In another feature, the system further comprises a controller configured to control the heater to anneal the bonded first and second subcomponents to form an annealed component.

In another feature, the controller is configured to control the heater to cool the annealed component to a first temperature at a first rate, and to cool the annealed component to a second temperature at a second rate. The second temperature is less than the first temperature. The first rate is slower than the second rate.

In another feature, the component is made of a nonmetallic material selected from a group consisting of silicon, silicon carbide, alumina, and ceramics.

In still other features, a system for repairing a component of a substrate processing system comprises a chamber under vacuum, and a rotary table arranged in the chamber to support the component thereon. The component has a defective portion in which a powdered material is disposed. The system comprises an arm arranged in the chamber parallel to the rotary table. The arm has a first end coupled to the rotary table and a second end extending out of the chamber. The system comprises a heater arranged in the chamber proximate to rotary table and the arm, and a thermal insulator arranged in the chamber forming a thermally insulated zone around the heater, the rotary table, and the arm. The system comprises an electron beam generator arranged in the chamber to direct an electron beam onto the powdered material through an opening in the thermally insulated zone to melt the powdered material and to repair the defective portion of the component.

In other features, the system further comprises a first actuator configured to rotate the rotary table around a first axis, a second actuator configured to rotate the arm and the rotary table around a second axis that is perpendicular to the first axis, and a third actuator configured to move the electron beam generator parallel to the rotary table along third and fourth axes that are perpendicular to each other.

In another feature, the system further comprises a controller configured to control the heater to heat the component to a predetermined temperature, and to control the electron beam generator to direct the electron beam onto the powdered material in the defective portion of the heated component.

In another feature, the system further comprises a controller configured to control the heater to anneal the repaired component.

In another feature, the controller is configured to control the heater to cool the annealed component to a first temperature at a first rate, and to cool the annealed component to a second temperature at a second rate. The second temperature is less than the first temperature. The first rate is slower than the second rate.

In other features, the component is made of a nonmetallic material selected from a group consisting of silicon, silicon carbide, alumina, and ceramics. The powdered material is the same nonmetallic material of which the component is made of.

In still other features, a system for building and repairing components of a substrate processing system comprises a chamber under vacuum, and a rotary table arranged in the chamber. The system comprises an arm arranged in the chamber parallel to the rotary table. The arm has a first end coupled to the rotary table and a second end extending out of the chamber. The system comprises a heater arranged in the chamber proximate to rotary table and the arm, and a thermal insulator arranged in the chamber forming a thermally insulated zone around the heater, the rotary table, and the arm. The system comprises a first electron beam generator arranged in the chamber to direct a first electron beam towards the rotary table through a first opening in the thermally insulated zone. The system comprises a second electron beam generator arranged in the chamber to direct a second electron beam towards the rotary table through a second opening in the thermally insulated zone.

In another feature, the first and second electron beams are perpendicular to each other.

In other features, the system further comprises a first actuator configured to rotate the rotary table around a first axis, a second actuator configured to rotate the arm and the rotary table around a second axis that is perpendicular to the first axis, a third actuator configured to move the first electron beam generator parallel to the rotary table along third and fourth axes that are perpendicular to each other, and a fourth actuator configured to move the second electron beam generator along the first axis.

In another feature, the system further comprises a controller configured to control the heater to heat a component arranged on the rotary table to a predetermined temperature, and to control at least one of the first and second electron beam generator to direct at least one of the first and second electron beams onto the heated component.

In other features, the component includes two pieces. The at least one of the first and second electron beams melts ends of the two pieces and bonds the two pieces together.

In other features, the component includes a defective portion in which a powdered material is disposed. The at least one of the first and second electron beams melts the powdered material to repair the defective portion of the component.

In another feature, the component is made of a nonmetallic material selected from a group consisting of silicon, silicon carbide, alumina, and ceramics.

In other features, the component is made of a nonmetallic material selected from a group consisting of silicon, silicon carbide, alumina, and ceramics. The powdered material is the same nonmetallic material of which the component is made of.

In another feature, the controller is configured to control the heater to anneal the heated component to form an annealed component.

In another feature, the controller is configured to control the heater to cool the annealed component to a first temperature at a first rate, and to cool the annealed component to a second temperature at a second rate. The second temperature is less than the first temperature. The first rate is slower than the second rate.

In still other features, a component comprises a first subcomponent and a second subcomponent. The first and second subcomponents are made of a material having a crystalline structure. The second subcomponent is bonded to the first subcomponent. A joint between the first and second components includes a grain boundary.

In another feature, the material includes a single crystalline structure.

In another feature, the material includes a multi-crystalline structure.

In another feature, the joint includes a powder of the material before the second subcomponent is bonded to the first subcomponent, and the joint includes a plurality of the grain boundary after the second subcomponent is bonded to the first subcomponent.

In another feature, the joint does not include a powder of the material before the second subcomponent is bonded to the first subcomponent, and the joint includes a plurality of the grain boundary after the second subcomponent is bonded to the first subcomponent.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

FIG. 1A shows an example of a graph for extraction kinetics of various materials, indicating removal efficiency of the materials as a function of temperature, for each of various elements commonly found in silicon;

FIG. 1B shows another example of a graph for extraction kinetics of various materials, indicating removal efficiency of the materials as a function of melting time, for each of various elements commonly found in silicon;

FIG. 2 shows an example of an e-beam system used to generate silicon vapor by heating a silicon boule;

FIG. 3 shows an example of a graph depicting a calculated maximum temperature of a top face of the silicon boule of FIG. 2 as a function of electron beam power;

FIG. 4 shows an example of an e-beam system to perform a continuous melting operation of silicon;

FIGS. 5A through 5C show exemplary embodiments of a system used for direct melting of silicon powder and a silicon block by e-beam melting;

FIG. 6 shows an example of a system to produce 3D components by e-beam-based additive manufacturing using high-purity silicon powders;

FIG. 7 shows an example of a graph showing silicon temperature as a function of time used to determine an appropriate build temperature for the silicon in accordance with various embodiments of the disclosed subject matter;

FIG. 8A shows an exemplary embodiment of a flow chart for preparing high-purity silicon powders in accordance with various embodiments; and

FIG. 8B shows an exemplary embodiment of a flow chart for forming three-dimensional (3D) components from silicon in a layer-by-layer process in accordance with various embodiments.

The present disclosure will become more fully understood from the detailed description and the accompanying drawings, wherein:

FIG. 9A shows an example of a substrate processing system comprising a processing chamber;

FIG. 9B shows an example of an electron beam generator providing an electron beam to a vacuum chamber for building a component using electron beam melting (EBM);

FIGS. 10A-10C show a powder bed based system for printing fully dense silicon materials on substrates according to the present disclosure;

FIG. 10D shows a system for selecting powders of nonmetallic materials for printing components using the systems and methods of the present disclosure;

FIG. 10E shows a system for manufacturing spherical shape, dense and doped powder of a material such as silicon using plasma rotating electrode processing (PREP);

FIG. 10F shows a system for manufacturing spherical shaped, dense, and doped powder of a material such as silicon using atmospheric pressure inductively coupled thermal plasma (ICTP);

FIG. 10G shows a temperature profile of a process performed by the system of FIG. 10F;

FIGS. 11A and 11B show a powder bed based method for printing fully dense nonmetallic materials on substrates according to the present disclosure;

FIGS. 12A and 12B show a powder bed based system for printing fully dense and crack free nonmetallic materials on nonmetallic substrates according to a high temperature powder bed method of the present disclosure;

FIG. 12C shows a powder bed based method for printing fully dense and crack free nonmetallic materials on nonmetallic substrates according to the high temperature powder bed method of the present disclosure;

FIGS. 13A-15B show various systems and methods for bonding and repairing silicon components using electron beam melting (EBM) according to the present disclosure; and

FIGS. 16A-16C show bonding of two silicon components using the systems and methods of FIGS. 13A-13C, 15A, and 15B resulting in a grain boundary between the two components due mismatched crystalline orientation.

In the drawings, reference numbers may be reused to identify similar and/or identical elements.

### DETAILED DESCRIPTION

The description that follows includes illustrative examples, devices, and apparatuses that embody various aspects of the disclosed subject matter. In the following description, for purposes of explanation, numerous specific details are set forth in order to provide an understanding of various embodiments of the inventive subject matter. It will be evident however, to those of ordinary skill in the art, that various embodiments of the disclosed subject matter may be practiced without these specific details. Further, well-known structures, materials, and techniques have not been shown in detail, so as not to obscure the various illustrated embodiments. As used herein, the terms “about” or “approximately” may refer to values that are, for example, within ±10% of a given value or range of values.

In various embodiments described herein, solutions to form 3D components (e.g., parts) from silicon use additive-manufacturing methods and additive-manufacturing tools to print the component layer-by-layer. Such methods and tools provide a highly precise and accurate final component. In embodiments, the disclosed subject matter uses a high-power beam, such as that emitted by an electron-beam (e-beam generator (gun)) or laser, to melt silicon powder and make silicon components in the aforementioned layer-by-layer manner to a near-net shape. In various embodiments employing the e-beam generator, the disclosed subject matter includes a powder-bed apparatus to assist in forming the printed components. The powder-bed apparatus is described in detail below.

As described in more detail below, because of the brittle nature of silicon materials, the ambient temperature for 3D silicon-based printing is generally performed at greater than about 1000° C. to prevent stress buildup and cracking. In some embodiments, the 3D silicon-based printing is generally performed at greater than about 1200° C. The 3D printed material may also be cooled slowly, also to prevent residual stresses and cracking.

In various embodiments, a temperature may be chosen that is above the temperature of a ductile-to-brittle transition temperature of silicon, as will be recognized by a person of ordinary skill in the art. The skilled artisan will further recognize that silicon is a brittle material at low temperatures, at which temperatures the silicon can shatter. Brittle materials can shatter due to stresses generated during rapid transitions from high temperatures to low temperatures. However, at elevated temperatures, the behavior of silicon changes. After a transition temperature is reached, silicon suddenly becomes ductile, much like many metallic materials. As is also explained in more detail below, the printed silicon components retain fewer residual stresses and fewer or no cracking issues occur if the printed silicon component is cooled down slowly, at a controlled and pre-determined rate, from the printing temperature of the silicon component.

Due to silicon high reactivity (especially when the silicon is melted) with an atmospheric ambient, such as oxygen (O₂), nitrogen (N₂), carbon dioxide (CO₂), carbon monoxide (CO), and other reactive gases, the disclosed subject matter performs silicon-printing operations in vacuum or in an inert gas (e.g., argon (Ar) or helium (He)). As is also described in more detail below, a substrate on which the silicon component is printed may also comprise silicon, Printing silicon-on-silicon reduces or avoids a coefficient-of-thermal-expansion (CTE) mismatch between materials. Further, employing a silicon substrate over substrates comprising other materials, such as metals, also helps to minimize or avoid contamination due to impurity diffusion from the non-silicon material into the printed silicon component. Effects of impurity diffusion increase at the high temperatures used during printing and annealing.

In various embodiments, the silicon powder used in the 3D printing process uses, for example, a fluidized-bed chemical vapor deposition (CVD) process. Silicon particles used in this process have a generally granular shape with a median size of approximately 50 μm and a distribution range between about 10 μm to about 100 μm. In embodiments, the purity of CVD silicon powder is generally greater than about 99.99%. In some embodiments, the purity of CVD silicon powder is generally greater than about 99.9999%. In embodiments, the silicon powder is baked in a range of about 700° C. (e.g., in a range of 650° C. to 750° C.) under high vacuum (e.g., about 10⁻⁶ Torr or in a range of 10⁻⁵ Torr to 10⁻⁷ Torr) to decompose and remove surface oxide (e.g., native oxide) before use of the silicon powder. The silicon powder used can be processed with a purity of greater than about 99.99% by various techniques described herein.

In various embodiments, and as described in more detail below, one 3D printing technology of the disclosed subject matter is powder-bed-based using an electron beam to melt the silicon powder. The silicon printing is performed layer-by-layer on a substrate, as described above. However, in contrast to 3D printing of metal-based materials, the systems and methods of the various embodiments of the disclosed subject matter consider other factors that affect printing quality when using silicon. Further, the disclosed subject matter includes, for example, a discussion of considerations involving particle morphology (e.g., substantially spherical particles versus other geometric forms, such as variants of polygonal volumes), as well as particle sizes and size ranges, and a distribution of the size ranges of the silicon powder.

Therefore, various embodiments of the disclosed subject matter can be highly generalized as three-step process: (1) form high-purity silicon; (2) prepare silicon powders from the high-purity silicon; and (3) use a 3D printing process employing the silicon powders. Each of these steps is explained in greater detail below in the form of exemplary embodiments.

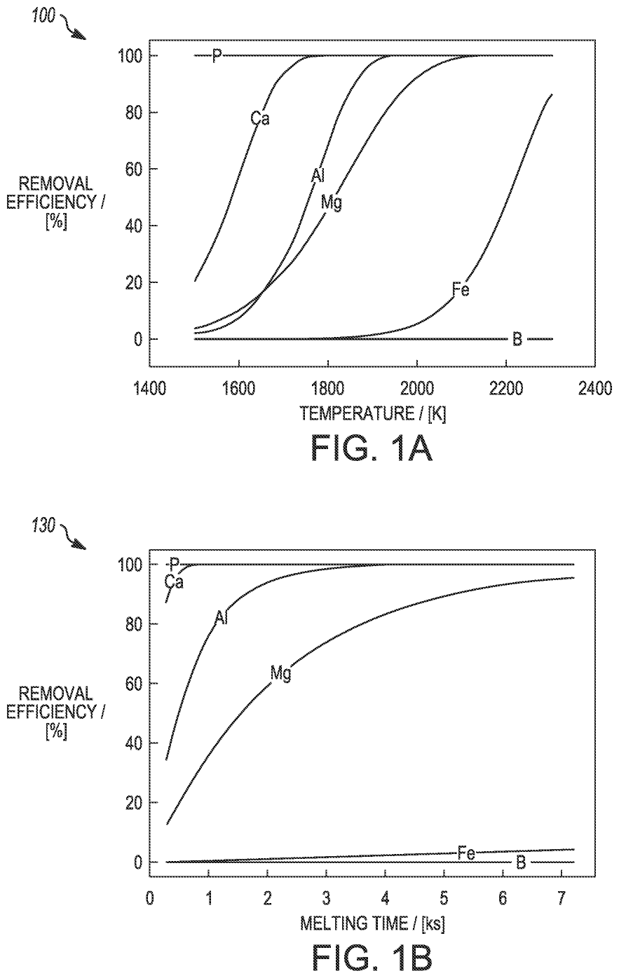

FIG. 1A shows an example of a graph 100 for extraction kinetics of various materials, indicating removal efficiency of the materials as a function of temperature, for each of various elements commonly found in silicon. The graph is based on a theoretical removal flux that assumes a perfect vacuum and that the impurity concentration follows Henry's law. As is known to a skilled artisan, Henry's Law, states that, at a constant temperature, the amount of a given gas dissolved in a given type and volume of liquid is proportional to its partial pressure in the gas phase. Consequently, Henry's law can therefore determine a mole fraction of a gas at a given time, t, versus the initial mole fraction at a given temperature.

The graph 100 of FIG. 1A therefore shows the removal efficiency for various elements to be extracted from, for example, a metallurgical-grade silicon (MG-Si) at a given temperature. High vapor-pressure impurities in, for example, MG-Si, are removed by vacuum during electron-beam melting. Impurities generally need to have a higher vapor pressure than silicon (which is about 1.6×10⁻³ Torr (approximately 0.21 Pa) at 1500° C.). Many of these elements are commonly found in Si. A vapor pressure at a given temperature may be found readily in the art for each of these elements.

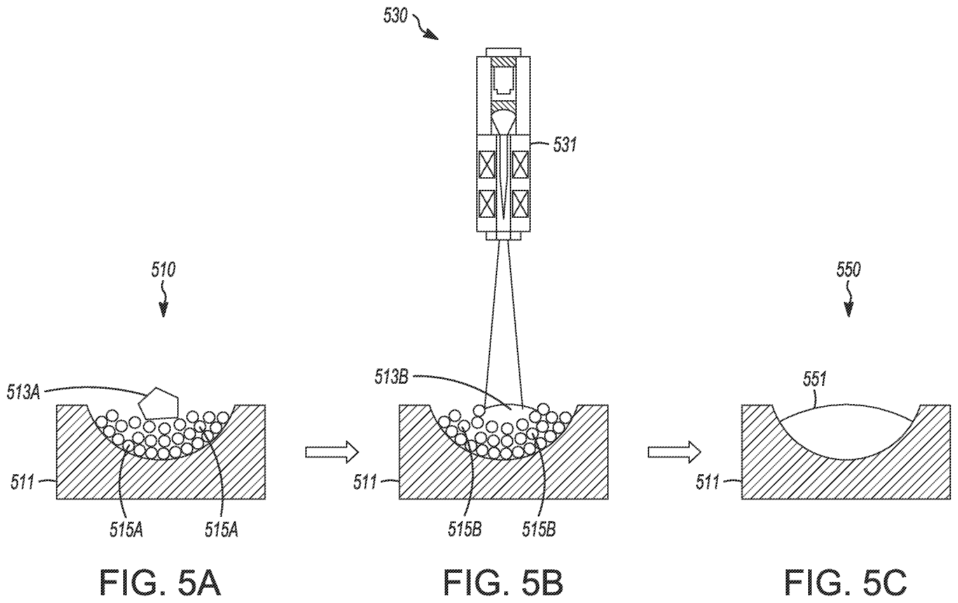

The elements shown in the graph include phosphorus (P), calcium (Ca), aluminum (Al), magnesium (Mg), iron (Fe), and boron (B). Consequently, for example, Ca asymptotically approaches 100% removal efficiency at about 1750 K and Mg asymptotically approaches 100% removal efficiency at about 2100 K. For the 3D-printed components formed from the processes described herein, a high-purity Si is typically used. However, as will be described in more detail below with reference to FIGS. 5A through 5C, there are advantages to using a more conductive version of Si (as compared with intrinsic Si). Therefore, some boron, which is not efficiently removed by an increased temperature alone, can actually be advantageous in that it allows the silicon to be more conductive than intrinsic silicon, thereby reducing or preventing a charge accumulation on silicon powders.

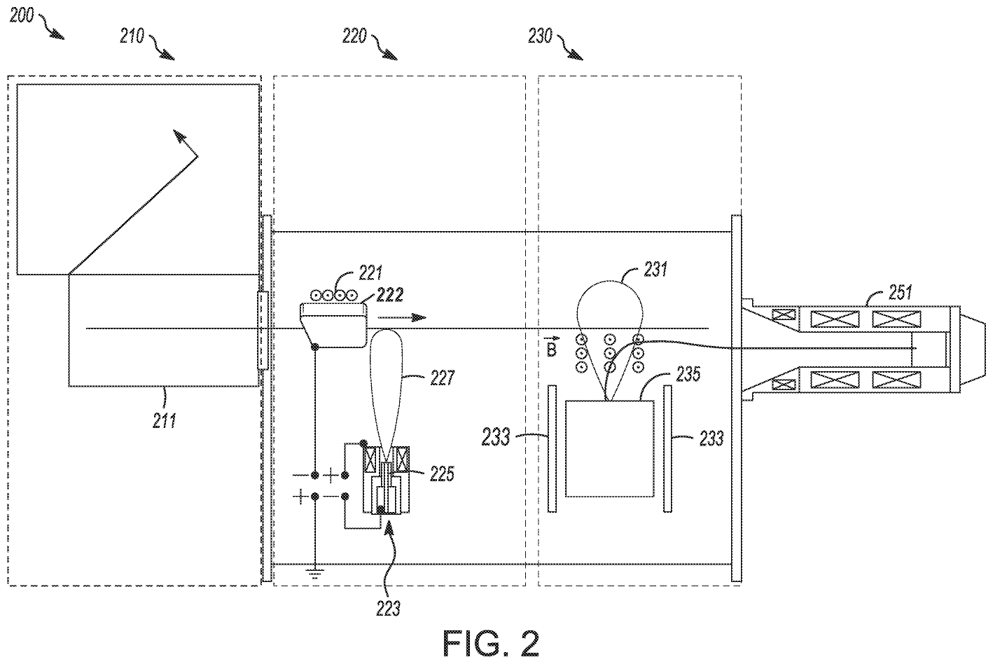

An electron-beam (e-beam) generator described below with reference to FIGS. 2, 4, and 5A through 5C may be employed to provide sufficient energy to raise the temperature of an MG-Si or EG-Si sample to at or above the temperatures shown. As is known in the art, intrinsic Si melts at about 1414° C. (approximately 1687 K) and has a boiling point of about 3265° C. (approximately 3538 K), both temperatures are given at atmospheric pressure (about 760 Torr or about 101.3 kPa).

FIG. 1B shows another example of a graph 130 for extraction kinetics of various materials, indicating removal efficiency of the materials as a function of melting time (in kiloseconds, ks) for each of various elements commonly found in silicon as described above. As is indicated by the graph, Ca asymptotically approaches 100% removal efficiency after about 0.75 ks (750 seconds), whereas Mg has only about a 95% removal after 7 ks.

FIG. 2 shows an example of an e-beam system 200 that may be used to generate silicon vapor by heating a silicon boule 235. As described above with reference to FIGS. 1A and 1B, the heating effect from an axially-mounted, e-beam generator 251 can be used to remove most or all impurities from the silicon boule 235 (e.g., an MG-Si boule). FIG. 2 is shown to include a substrate load portion 210, a pre-treatment portion 220, and a silicon-deposition portion 230.

The substrate load portion 210 may comprise an inert-gas (e.g., an argon (Ar) or helium (He)) environment in which a load-lock chamber 211 provides an entry point for a substrate 222 into the e-beam system 200. In a specific exemplary embodiment, the substrate 222 comprises silicon (e.g., a silicon wafer). After the substrate 222 is loaded, an entirety of the e-beam system 200 may be evacuated to a pre-determined vacuum level (e.g., 10-6 Torr or some other level to provide a desired level of vacuum for operation of the e-beam generator 251 and deposition of Si particles onto the substrate 222, as explained below).

As the substrate 222 continues along a path within the e-beam system 200, the substrate 222 may be heated by a, for example, backside radiation heater 221 or other type of radiant heater known in the art. The substrate 222 may be heated to, for example, 50° C. to 200° C. or higher.

As shown, a negative bias voltage is applied to the substrate 222 as the substrate traverses a plasma volume 227 generated by, in this embodiment, a hollow-cathode, arc-discharge plasma generator 225. A noble, ultra-pure gas (e.g., Ar) is delivered 223 to the plasma generator 225 to create gaseous ions (in this case, Ar ions). The gaseous ions in the plasma volume 227 are accelerated to the substrate 222 in the pre-treatment portion 220 by the bias voltage applied to the substrate 222.

As is known in the art, the gaseous ions provide cleaning of the substrate 222 by a sputtering effect, thereby cleaning surface contaminants from a surface of the substrate 222 that is proximate to the plasma generator 225. The substrate then continues into the silicon-deposition portion 230 of the e-beam system 200.

E-beams generated by the e-beam generator 251 are deflected toward a surface of the silicon boule 235 by a strong magnetic field. The silicon boule 235 is mounted within a quartz radiation-shield 233. The e-beam is regulated to provide a slow heating level of the silicon boule 235 up to a brittle-to-ductile transition temperature of silicon, or higher, to reduce or prevent cracking. In a specific exemplary embodiment, a temperature ramp-rate of about 50 K per minute may be used to reduce or prevent cracking. At this temperature ramp-rate, a temperature of approximately 800° C. (about 1073 K) can be achieved in approximately 15.5 minutes. In various embodiments, the ramp rate be determined by, for example, finite-element analysis comparing heat flux and induced mechanical stresses. An uppermost surface of the silicon boule 235 begins to melt, producing a cloud of Si vapor 231, which is then deposited on the substrate 222 once the substrate 222 is moved into position over the silicon boule 235. The Si particles are deposited onto the substrate 222 by a physical vapor deposition process. A thickness of the deposited Si onto the substrate is determined by a pre-determined time in which the substrate remains over the silicon boule 235 and within the cloud of Si vapor 231.

After an entirety of the silicon boule 235 reaches the brittle-to-ductile transition temperature, rapid heating occurs to the melt temperature of the silicon. The brittle-to-ductile transition temperature may be estimated by measured temperatures at several locations along the silicon boule 235, combined with a finite-element simulation.

Once removed from the e-beam system 200, the silicon coating (which may be formed as a crystalline layer over the substrate 222) that was deposited on the substrate 222 may be removed from the substrate 222. The substrate 222 may then be reused within the e-beam system 200.

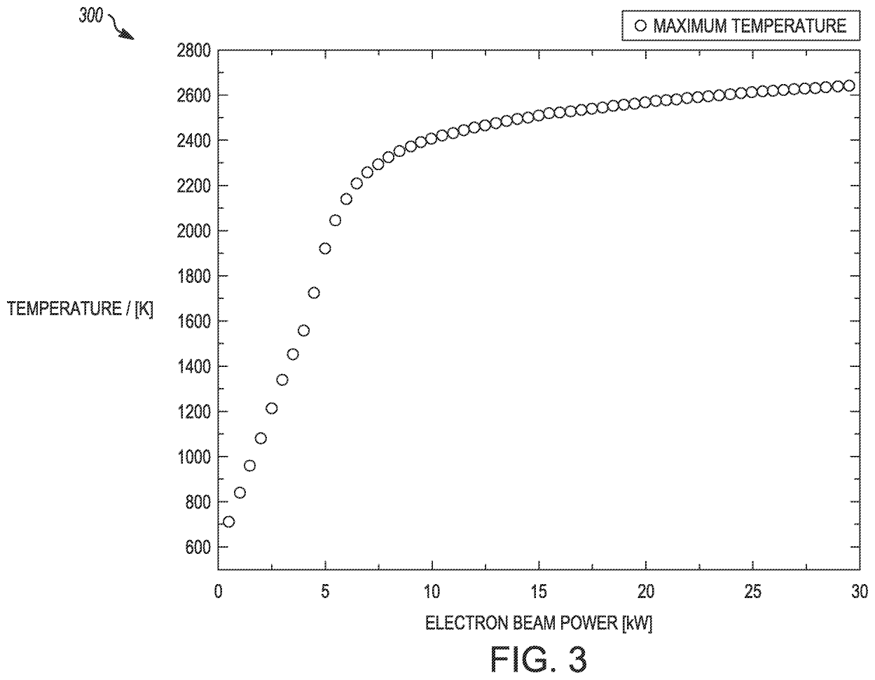

With reference now to FIG. 3, an example of a graph 300 depicting calculated maximum temperature of a top face of the silicon boule 235 of FIG. 2 is shown as a function of electron beam power. In this example, a desired thermal equilibrium temperature at steady state of about 1000° C. (approximately 1273 K) is reached with about 3 kW of power input to the silicon. Recall that various embodiments of the disclosed subject matter use a temperature of about 1000° C. brittle-to-ductile transition temperature of silicon to reduce or prevent cracking. As shown in FIG. 3, the maximum temperature rises nearly linearly with increased e-beam power up to about 5 kW. Above 5 kW for the embodiment depicted by FIG. 2, thermal losses from radiation and evaporation become dominant and the slope of the curve of temperature as a function of e-beam power changes.

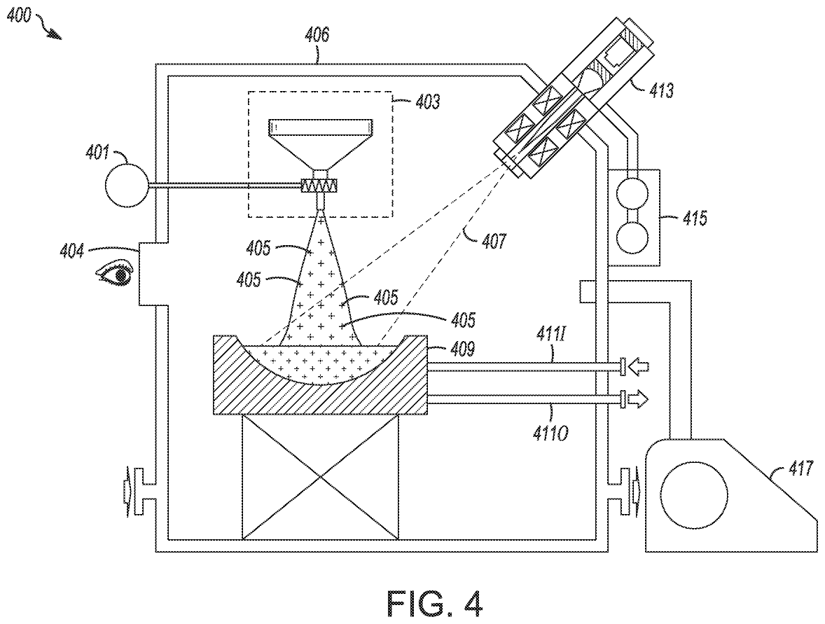

FIG. 4 shows an example of an e-beam system 400 to perform a continuous melting operation of silicon. The e-beam system 400 is shown to include a vacuum chamber 406, a silicon-powder feed hopper 403, a sensor 401 to monitor a mass of silicon powder 405 leaving the feed hopper 403, a cooled crucible 409 (e.g., a water-cooled copper crucible in one specific exemplary embodiment), an input cooling-line 4111 and an output cooling-line 4110, an observation port 404, a pump 417 to evacuate the vacuum chamber 406 (e.g., down to approximately 10⁻⁶ Torr or to some pre-determined level of vacuum) an e-beam generator 413 to produce an electron beam 407, and an e-beam controller 415. The e-beam generator 413 may be the same as or similar to the e-beam generator 251 of FIG. 2. In a specific exemplary embodiment, the e-beam generator 413 can supply up to 300 kW of power. However, as noted above, the e-beam generator 413 is controlled by the e-beam controller 415 to heat the silicon powder 405 slowly to reduce or prevent cracking of the silicon.

As the silicon powder 405 is fed into the cooled crucible 409, the electron beam 407 melts the silicon powder 405. In various embodiments, once the silicon powder 405 is melted and a desired mass or volume of melted silicon is collected in the crucible 409, the crucible 409 may be cooled slowly, as described above, by transferring a cooling fluid (e.g., water) through the input cooling-line 4111 and out of the output cooling-line 4110. Along with the cooling provided to the melted silicon by the crucible 409, the power of the electron beam 407 emitted by the e-beam generator 413 may also be reduced slowly at a pre-determined ramp-down rate as described above. To prevent copper contamination into the silicon powder 405, the silicon is not fully melted in the crucible 409. The portion of the silicon powder 405 that is close to interior sidewalls of the crucible 409 will be at a temperature similar to that of the crucible 409, thereby preventing potential copper contamination of the silicon powder 405.

FIGS. 5A through 5C show exemplary embodiments of a system used for direct melting of silicon powder and a silicon block by e-beam melting. Although not shown explicitly, the embodiments of FIGS. 5A through 5C are carried out under vacuum, as described above. Further, various components of the system of FIGS. 5A through 5C may be the same as or similar to related ones of the various components described above with reference to FIG. 4. For example, an e-beam generator 531 may be the same as or similar to the e-beam generator 413 of FIG. 4. Also, a crucible 511 may be the same as or similar to the crucible 409 of FIG. 4.

In this embodiment, a silicon block 513A at operation 510 of FIG. 5A is added to silicon powder 515A by a direct melting process as shown at operation 530 in which the silicon block 513A, when exposed to the e-beam generator 531, forms a now partially-melted silicon block 513B. The partially-melted silicon block 513B enables continuous melting of the silicon and infiltrates into the now partially-melted silicon powder 551B, resulting in a silicon ingot 551 at operation 550. As with the systems of FIGS. 2 and 4 described above, various ramp-up rates and ramp-down rates of temperature are controlled to reduce or prevent cracking of the silicon ingot 551.

Once high-purity silicon is obtained from the various methods described above, the silicon is changed into a powdered form for the printing operation by various methods. For example, silicon powder may be generated by a fluidized-bed chemical vapor deposition (FB-CVD) system using silane (SiH₄)-gas atomization processing. Silicon powder may also be generated by plasma rotation electrode processing (PREP). In FB-CVD, silane is deposited on small silicon particles. In the gas atomization process, silicon is melted under inert gas blanket or under vacuum. The molten silicon is forced through a nozzle where high-velocity helium (He) or argon (Ar) gas breaks the silicon into fine silicon particles. The gas atomization process and FB-CVD generate satellite silicon particles (e.g., powdered silicon), which affects powder flowability and therefore printing quality. In plasma rotating electrode processing, a silicon rod is used as feedstock and rotates rapidly inside a chamber. A plasma torch melts the end of silicon rod while it is in high-speed rotation. Centrifugal force ejects molten silicon from the silicon rod, where it solidifies into fine, substantially-spherical particles. This process generates high purity and substantially-uniform silicon powder particles since melting and solidification occur in inert gas environment. A morphology of the silicon particles can be adjusted by adjusting a rotational speed of the silicon rod.

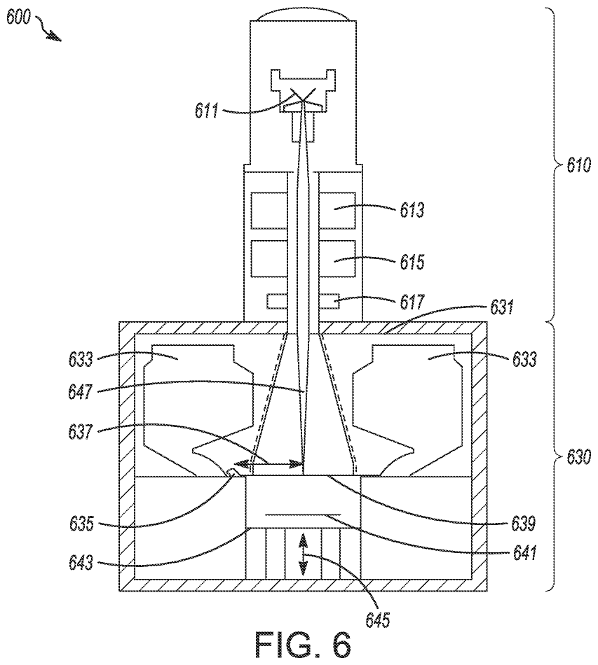

FIG. 6 shows an example of a system 600 to produce 3D components by e-beam-based additive manufacturing using high-purity silicon powders. Such a system 600 that can be used with the novel silicon-powder generation techniques described herein is available from, for example, Arcam AB, Krokslätts Fabriker 27A, SE 431 37 Mölndal, Sweden.

With continuing reference to FIG. 6, the system 600 is shown to include an electron beam (e-beam) column 610 and a 3D printing chamber 630. A filament 611 of the e-beam column 610 generated an e-beam 647 that traverses through an astigmatism lens 613, a focus lens 615, and a deflection lens 617. The astigmatism lens 613 and the focus lens 615 prepare a collimated version of the e-beam 647 that can be driven to various x-y coordinates on a substrate 641 located above a build platform 643 as described in more detail below. Since the 3D component to be printed is formed from silicon powder, the substrate 641 can also be formed from silicon to reduce or eliminate any stresses from a CTE mismatch, as described above. In various embodiments, the silicon substrate 641 may be chosen to have a desired epitaxial structure, which may be used to generate a matching epitaxy in the printed component. In other embodiments, the substrate 641 can be formed from steel, coated or uncoated, or another non-contaminating material having a CTE similar to that of silicon but having a higher melting point. However, depending upon the application, consideration should be given to whether other materials may diffuse into bulk silicon. In other embodiments, the substrate 641 may also comprise an existing silicon part or silicon component onto which additional material is to be added.

The x, y, and z coordinates are added to, for example, a computer-aided design (CAD) program, from a pre-determined CAD file, into a computer (not shown), such as a personal computer, a micro-processor, a controller, or other type of device capable of running the CAD program and driving the deflection lens 617. Such a device will be recognizable to a person of ordinary skill in the art, upon reading and understanding the disclosed subject matter provided herein. Further, the skilled artisan will recognize that the z coordinates of the CAD file indicate a height over which the 3D component is to be formed. An executable program within the system 600 effectively “slices” the z coordinates into thicknesses that correspond to a thickness of a silicon layer to be printed. Each of the z slices is formed at a different z height by moving the substrate, as described below.

With continuing reference to FIG. 6, the 3D printing chamber 630 includes a vacuum chamber 631. In various embodiments, the vacuum chamber 631 may be evacuated to a level of less than, for example, about 75·(10⁻⁶) Torr. In various embodiments, the vacuum chamber 631 may be evacuated to a level of less than, for example, about 10⁻⁵ Torr. Within the vacuum chamber 631, one or more hoppers 633 hold the pre-loaded and pre-sized silicon powder. The silicon powder is formed into a volume above the substrate 641 and the build platform 643. A rake 635 then moves mechanically in a horizontal direction 637 above the silicon powder that has been dropped form the one or more hoppers 633 to create a pre-determined thickness of silicon powder above the substrate 641. As the e-beam 647 is energized and driven in x-y coordinates based on the pre-determined pattern (from the CAD file, described above), the energy from the e-beam 647 melts the silicon powder creating a pattern in silicon of the 3D component being printed, layer-by-layer. In various embodiments, a thickness of a layer may be in a range of about 30 μm to about 60 μm.

After a layer is printed, the substrate 641 is raised by the build platform 643 in a direction 645 such that subsequent layers of a 3D component being printed on the substrate 641 can be lowered from an uppermost location 639 of the powder bed after each layer is printed. The rake 635 levels a subsequent silicon powder bed deposited from the one or more hoppers 633 and the process continues until the 3D component is fabricated. Once the 3D component is completed, the power applied to the e-beam 647 may be ramped down slowly at a pre-determined ramp rate, as described above, to reduce or prevent any stress cracking the component.

In various embodiments, a power level of the e-beam 647 may be selected to be from about 50 W to about 300 W. A full-width, half maximum (FWHM) diameter of the e-beam 647 at the build platform 643 is selectable from about 200 μm up to about 10 mm. The e-beam 647 can be driven by the deflection lens 617 at a velocity of up to about 8000 meters per second (m/s). Depending on a number of factors including, for example, build material and build complexity of the printed part, the system 600 can have a built rate of from about 55 to about 80 cubic centimeters per hour (cm³/h). Although the system 600 of FIG. 6 shows only a single e-beam, in various embodiments, up to about 100 e-beams may be generated.

In a specific exemplary embodiment, an energy density of the e-beam 647 at a surface of the build platform 643 is about 28 Joules per cubic millimeter (J/mm³), with a diameter (e.g., spot size) of the e-beam 647 being about 100 μm, driven at a velocity of about 2.9 m/s. In other embodiments, the e-beam spot size may be from about 350 μm to about 2000 μm. The beam current may be about 30 mA for initial heating of the silicon powder with a beam current for about 5 mA to about 10 mA for final heating. Also, the substrate 641 may be heated to a temperature in a range of about 150 K to about 250 K below the melt temperature of silicon (e.g., the substrate 641 may be heated to about 1130° C.).

In various embodiments, a number of “buffer layers” of silicon may initially be printed onto the substrate 641, followed by layers of printed silicon for the actual component. The buffer layers may be printed at a faster rate than the rate at which the subsequent silicon layers are printed on the buffer layers to print the component. Using buffer layers of silicon reduces any CTE-expansion mismatch between a non-silicon substrate 641 and the silicon layers printed on the buffer layers if the non-silicon substrate 641 is not formed from silicon or a material having a similar CTE as silicon. Without the buffer layers, a large CTE mismatch can exist between the substrate 641 and the silicon layers printed directly on the substrate 641 to print a component. The CTE mismatch can lead to potential fracture or fractures in the printed component. Printing using a buffer layer typically only applies when the non-silicon substrate 641 is used. The buffer layer consists of, for example, about 50 to about 100 layers printed at a faster rate than a subsequent normal silicon-printing. Once buffer-layer printing is completed, the silicon printing starts with a normal printing rate. If silicon substrate is used, the buffer-layer printing may be skipped.

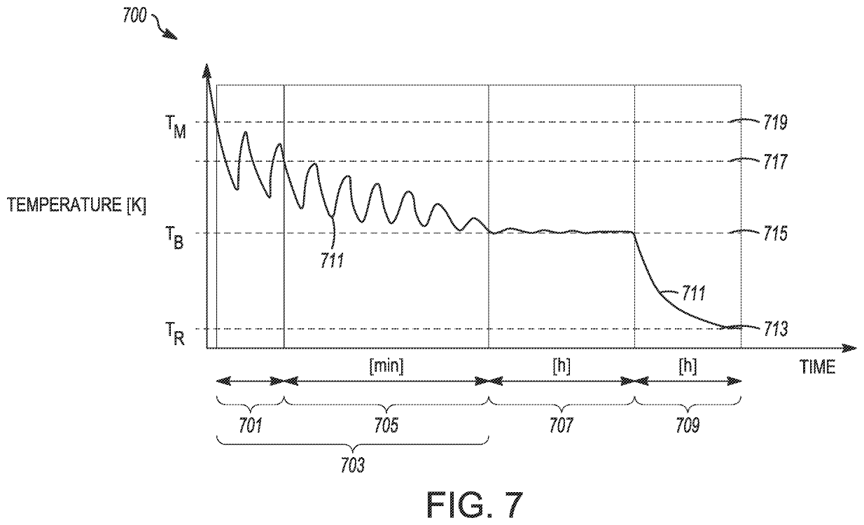

With reference now to FIG. 7, an example of a graph 700 showing silicon temperature 711 as a function of time is shown and is used to determine an appropriate build temperature, TB, for the silicon powder in accordance with various embodiments of the disclosed subject matter. The graph 700 indicates the temperature evolution of a fixed point in a printed component where the e-beam (e.g., the e-beam 647 of FIG. 6) passes several times in each layer in the layer-by-layer construction of the printed component as described above with reference to FIG. 6. The graph 700 shows a solidification temperature line 719, a phase-transition temperature line 717, a build temperature line 715, and an ambient temperature line 713.

Below the solidification temperature line 719, the silicon begins to solidify. Above the solidification temperature line 719, the silicon melts (the melt temperature, Tnn). A first time period 701 occurs over a time lasting from several seconds to several minutes or more, and depends at least partially upon a selected cooling ramp-down rate, a temperature to which the silicon particles are heated, and a velocity over which the e-beam passes by a given spatial point in the printed component. A second time period 705 occurs approximately after the silicon temperature 711 has passed below the phase-transition temperature line 717 up until the build temperature line 715 is reached (the build temperature, TB). The second time period 705 may continue over a period of minutes. As noted by the graph 700, the silicon temperature 711 curve oscillates within an oscillation time period 703. The oscillations in temperature are due to heating of adjacent regions or adjacent layers within the printed component. A third time period 707 over which the build temperature, TB, is maintained is selectable depending upon various factors chosen to perform operations to form the printed component, as described above, as well as a complexity and physical size of the build. Therefore, the third time period 707 may last several hours. After the component is fully printed, the silicon temperature 711 ramps down, depending upon the cooling ramp-down rate selected, until the ambient temperature line 713 is reached. The ambient temperature line 713 in many embodiments is considered to be at room temperature, TR (e.g., about 20° C. to about 25° C.). A fourth time period 709 over which the component cools may extend for several hours. In a specific exemplary embodiment, the descending temperature of the ramp-down rate is less than about 5° C. per minute from the build temperature, down to approximately 400° C. or lower. An inert gas (e.g., Ar or He) may then be pumped into the processing chamber.

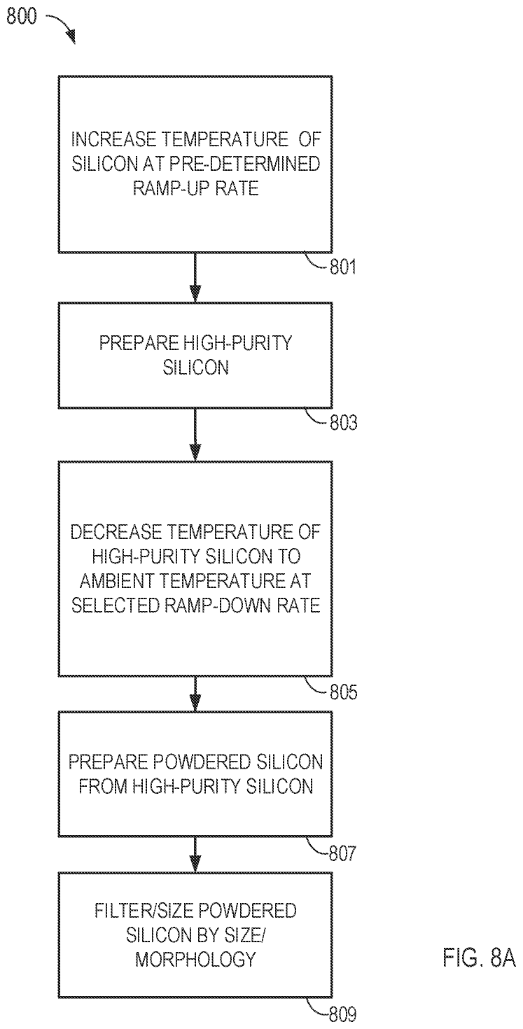

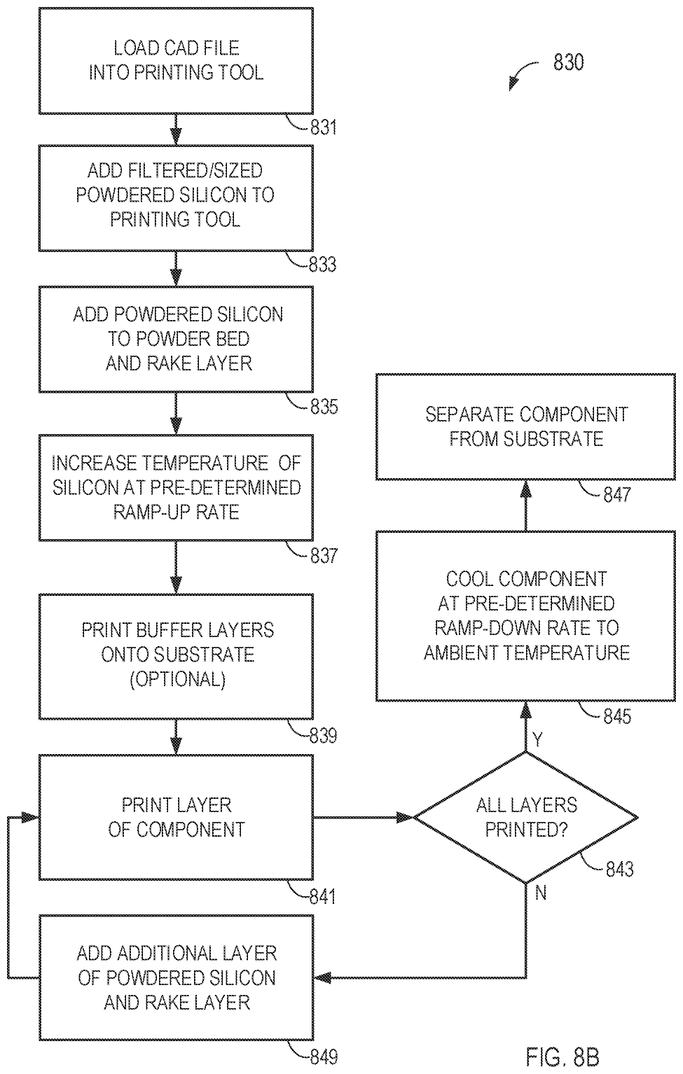

Referring now to FIG. 8A, an exemplary embodiment of a flow chart 800 for preparing high-purity silicon powders in accordance with various embodiments is shown. Many or all of the operations described below are made with reference to various embodiments already described above. For example, the operations of the flow charts 800 of FIG. 8A and 830 of FIG. 8B refer to various temperature ramp-up rates, temperature ramp-down rates, means of producing high-purity silicon, and printing various components. Each of these techniques, procedures, and associated apparatuses and system are described above. Further, as described in more detail below, one or more of the various processes and operations may be formed in an order other than what is shown explicitly within the figures. Therefore, unless otherwise stated, nothing requires that the operations necessarily be performed in the order illustrated.

With continuing reference to FIG. 8A, at operation 801, silicon is placed or otherwise formed within an apparatus (such as in, for example, the crucible 409 of the e-beam system 400 of FIG. 4). The temperature of the silicon is increased at a pre-determined ramp-up rate. At operation 803, high-purity silicon is prepared or otherwise formed in accordance with various exemplary embodiments described above (for example, with reference to one or more of FIGS. 2, 4, and 5A through 5C). Once the high-purity silicon is prepared or otherwise formed, at operation 805, the temperature of the silicon is decreased at a pre-determined temperature ramp-rate down to, for example, ambient temperature (e.g., such as room temperature, TR, as described with reference to FIG. 7). At operation 807, powdered silicon is prepared or otherwise formed from the high-purity silicon. The powdered silicon is then filtered and/or sized by size and/or morphology at operation 809. For example, the powdered silicon may be sized through the use of mechanical sieves, known in the art. However, in various embodiments, sizing and filtering processes are performed within an inert-gas environment (e.g., Ar or He) to prevent native oxide from forming on surfaces of the silicon.

FIG. 8B shows an exemplary embodiment of a flow chart 830 for forming three-dimensional (3D) components from silicon in a layer-by-layer process in accordance with various embodiments. For example, a person of ordinary skill in the art may find that concurrent reference to FIG. 6, and the accompanying text, may increase understanding of at least some of the operations described below with reference to FIG. 8B.

At operation 831, the CAD file is loaded into the printing tool (e.g., the system 600 of FIG. 6). Filtered and/or sized powdered silicon is added into the printing tool (e.g., into the one or more hoppers 633) at operation 833. As noted above, in a specific exemplary embodiment, the powdered silicon is maintained in an inert-gas environment to avoid native oxide (SiO₂ or SiₓO_{y}) growth on the silicon particles. In certain applications, the native oxide may be considered to be a contaminant for printing certain types of 3D components from silicon.

At operation 835, the powdered silicon is added into the powder bed and the powder bed is raked to form a substantially uniform layer of silicon of a pre-determined thickness. The temperature of the silicon is increased at operation 837 (e.g., by the e-beam 647 of the system 600) at a pre-determined ramp-up rate in accordance with various embodiments described above.

If buffer layers are desirable (e.g., when using a build table, such as the substrate 641, when the substrate is formed from a material with a CTE value not substantially matching that of silicon as described above), one or more buffer layers may optionally be printed prior to beginning printing of the actual 3D component at operation 839. Such buffer layers may be printed onto the substrate to, for example, either mimic a lower portion of the 3D component to be printed or may alternately be printed over an entirety or near entirety of an uppermost surface of the substrate.

At operation 841, a first layer of the 3D component is printed, either onto the substrate directly or onto the one or more buffer layers. A determination is made (for example, within the CAD program) at operation 843 as to whether all layers of the silicon component have been printed. If all layers have been printed, the component is cooled at the pre-determined ramp-down rate of temperature to, for example, ambient temperature, at operation 845. The silicon component is removed from the printing tool and then separated from the substrate at operation 847.

If at operation 843, a determination has been made that not all layers have been printed, the flow chart 830 continues to the print layer of component at operation 841.

The following numbered examples are specific embodiments of the disclosed subject matter.

Example 1: A method of performing three-dimensional (3D) printing of a silicon component, the method including adding powdered silicon to a 3D printing tool. For each layer of the 3D printing in a layer-by-layer process: forming a powder bed of the powdered silicon in the 3D printing tool, baking the powdered silicon in a temperature range of 650° C. to 750° C. under a high-vacuum condition in a range of 10⁻⁵ Torr to 10⁻⁷ Torr to decompose and remove surface oxides from the powdered silicon, forming a layer of the powder bed to a pre-determined thickness, directing a high-powered beam under the high-vacuum condition in a pre-determined pattern into the formed powder-bed, the high-powered beam having sufficient energy to melt the powdered silicon, and making a determination as to whether additional layers in the 3D printing are needed. Based on a determination that no additional layers are needed, cooling the silicon component at a pre-determined temperature ramp-down rate to about ambient temperature of an environment in which the 3D printing tool is located.

Example 2: The method of example wherein the high-powered beam comprises an electron beam.

Example 3: The method of any one of the preceding Examples, wherein the method is performed within an inert gas environment.

Example 4: The method of Example 3, wherein the inert gas environment comprises at least one gas selected from gases including argon (Ar) and helium (He).

Example 5: The method of any one of the preceding Examples, wherein silicon particles in the silicon powder have a median size in a range of about 45 μm to about 55 μm and a distribution range of sizes between about 10 μm to about 100 μm.

Example 6: The method of any one of the preceding Examples, wherein a purity of the powdered silicon is generally greater than about 99.99%.

Example 7: The method of any one of the preceding Examples, wherein a purity of the powdered silicon is generally greater than about 99.9999%.

Example 8: The method of any one of the preceding Examples, wherein the powdered silicon is baked in a temperature range of about 700° C. under a high-vacuum condition in a range of about 10-6 Torr to decompose and remove surface oxides from the powdered silicon.

Example 9: The method of any one of the preceding Examples, wherein the powdered silicon comprises substantially spherical particles.

Example 10: The method of any one of the preceding Examples, wherein the powdered silicon is formed by a fluidized-bed chemical vapor deposition (FB-CVD) system using silane (SiH₄)-gas atomization.

Example 11: The method of Example 10, further including preparing molten silicon, forcing the molten silicon through a nozzle, directing a high-velocity gas stream at the molten silicon, the high-velocity gas stream comprising at least one gas selected from gases including helium (He) and argon (Ar) to break the molten silicon into silicon particles to form the powdered silicon, and depositing silane on the silicon particles.

Example 12: The method of any one of the preceding Examples, wherein the powdered silicon is formed by plasma rotation electrode processing (PREP).

Example 13: The method of Example 12, further including melting an end of a silicon rod while the silicon rod is rotated, a rotational speed of the silicon rod being sufficient to create a centrifugal force to eject molten silicon from the silicon rod, and solidifying the ejected molten silicon into silicon particles to from the powdered silicon.

Example 14: The method of Example 13, further including adjusting a morphology of the silicon particles by adjusting the rotational speed of the silicon rod.

Example 15: The method of any one of the preceding Examples, wherein the pre-determined temperature ramp-down rate is less than about 5° C. per minute.

Example 16: The method of any one of the preceding Examples, further including preparing high-purity silicon by operations including: placing silicon into a crucible, increasing a temperature of the silicon at a pre-determined ramp-up rate, at least partially melting the silicon with high-powered beam, the high-powered beam having a power sufficient to melt the silicon, and decreasing the temperature of the silicon at a second pre-determined ramp-down rate.

Example 17: The method of Example 16, wherein the pre-determined ramp-up rate of temperature is determined by finite-element analysis including comparing heat flux and induced mechanical stresses in the silicon.

Example 18: The method of Example 16, wherein the temperature ramp-rate is about 50 K per minute.

Example 19: The method of any one of the preceding Examples, wherein the pre-determined thickness of each layer in the layer-by-layer process is within a range from about 30 μm to about 50 μm.

Example 20: A method of performing three-dimensional (3D) printing of a silicon component, the method including loading a design file into a 3D printing tool where the design file containing geometries of the silicon component including coordinates for each of multiple layers to print the silicon component. For each layer of the 3D printing of the silicon component: forming a powder bed of powdered silicon in the 3D printing tool, baking the powdered silicon in a temperature range of 650° C. to 750° C. under a high-vacuum condition in a range of 10⁻⁵ Torr to 10⁻⁷ Torr to decompose and remove surface oxides from the powdered silicon, raking a layer of the powder bed to a pre-determined thickness, directing an electron beam under the high-vacuum condition in a pre-determined pattern into the raked powdered-bed, the pre-determined pattern being based on the design file, the electron beam having sufficient energy to melt the powdered silicon, and making a determination as to whether additional layers in the 3D printing are needed. Based on a determination that no additional layers are needed, cooling the silicon component at a pre-determined temperature to about ambient temperature in which the 3D printing tool is located.

Example 21: The method of Example 20, wherein the design file is a computer-aided design file.

Example 22: The method of any one of the preceding Examples 20 et seq., wherein silicon particles in the silicon powder have a median size of approximately 50 μm and a distribution range of sizes between about 10 μm to about 100 μm.

Example 23: The method of any one of the preceding Examples 20 et seq., wherein a purity of the powdered silicon is generally greater than about 99.99%.

Example 24: The method of any one of the preceding Examples 20 et seq., wherein a purity of the powdered silicon is generally greater than about 99.9999%.

Example 25: The method of any one of the preceding Examples 20 et seq., wherein the powdered silicon is baked at about 700° C. under high vacuum condition of about 10-6 Torr to decompose and remove surface oxides from the powdered silicon.

Example 26: The method of any one of the preceding Examples 20 et seq., wherein the powdered silicon comprises substantially spherical particles.

Example 27: The method of any one of the preceding Examples 20 et seq., wherein a power level of the electron beam is in a range from about 50 W to about 300 W.

Example 28: The method of any one of the preceding Examples 20 et seq., wherein a full-width, half maximum (FWHM) diameter of the electron beam at a build platform upon which the silicon component is being formed is in a range from about 200 μm up to about 10 mm.

Example 29: The method of any one of the preceding Examples 20 et seq., wherein an energy density of the electron beam at a surface of the build platform is about 28 Joules per cubic millimeter (J/mm³).

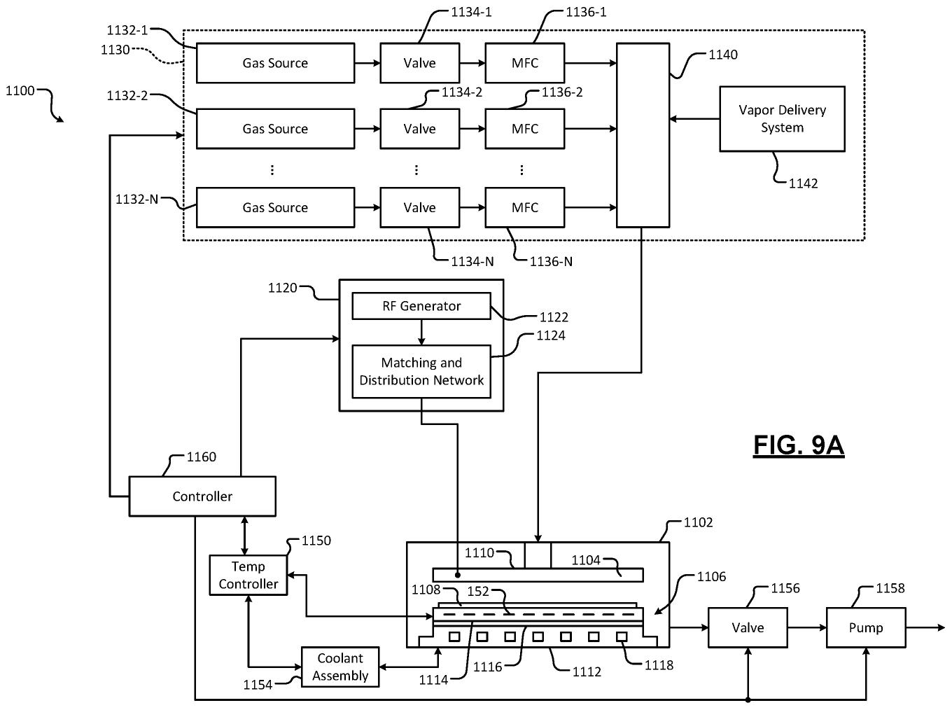

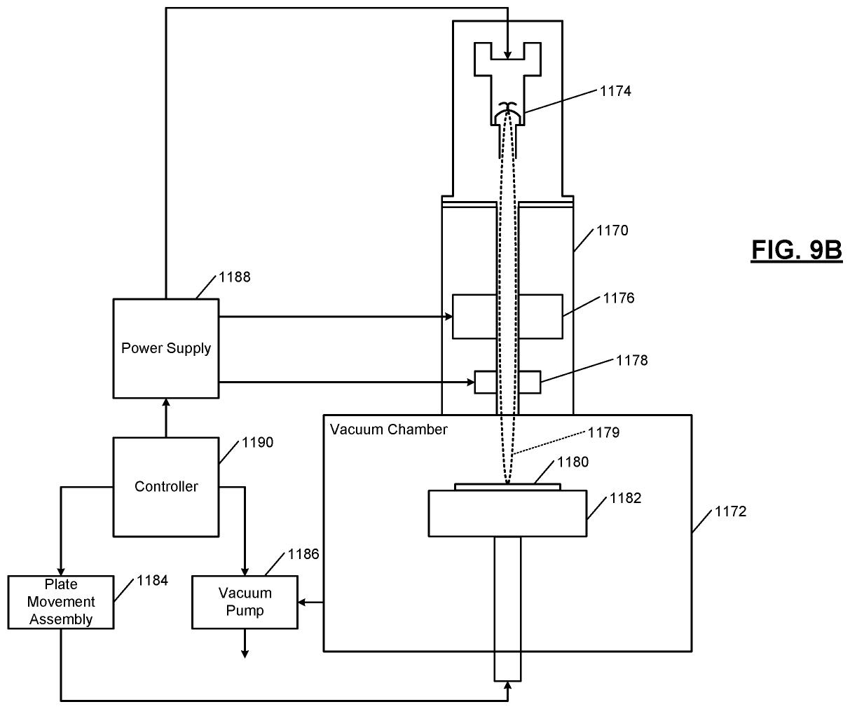

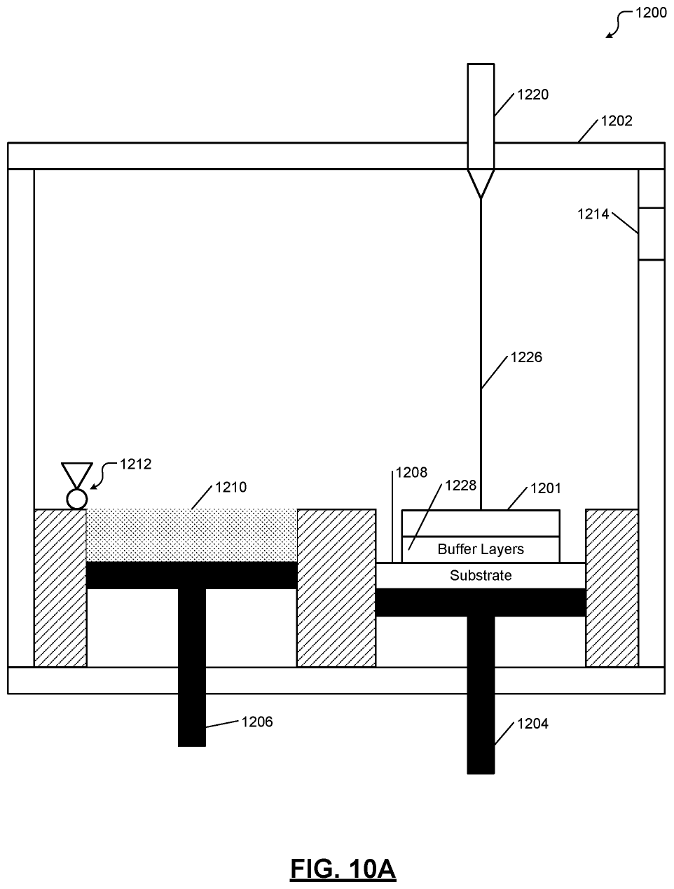

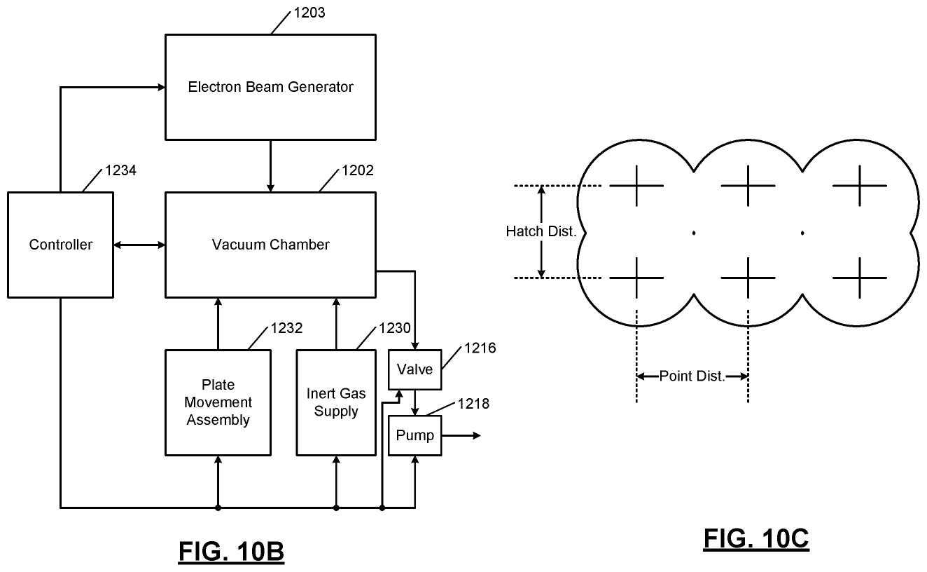

Various components used in substrate processing systems and processing chambers are manufactured with high precision. Some of these components are made of metals while others are made of materials such as silicon and ceramics. An example of a substrate processing system and a processing chamber is shown and described below with reference to FIG. 9A to provide examples of these components and the harsh electrical, chemical, and thermal environments in which these components operate. The present disclosure relates to systems and methods for printing these components using electron beam melting (EBM).

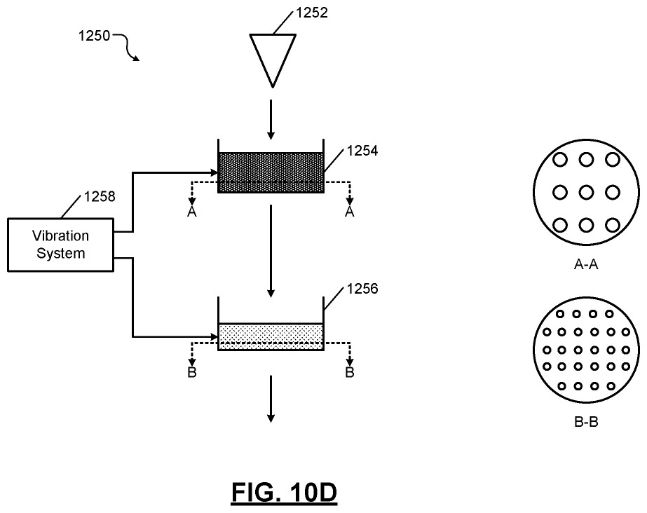

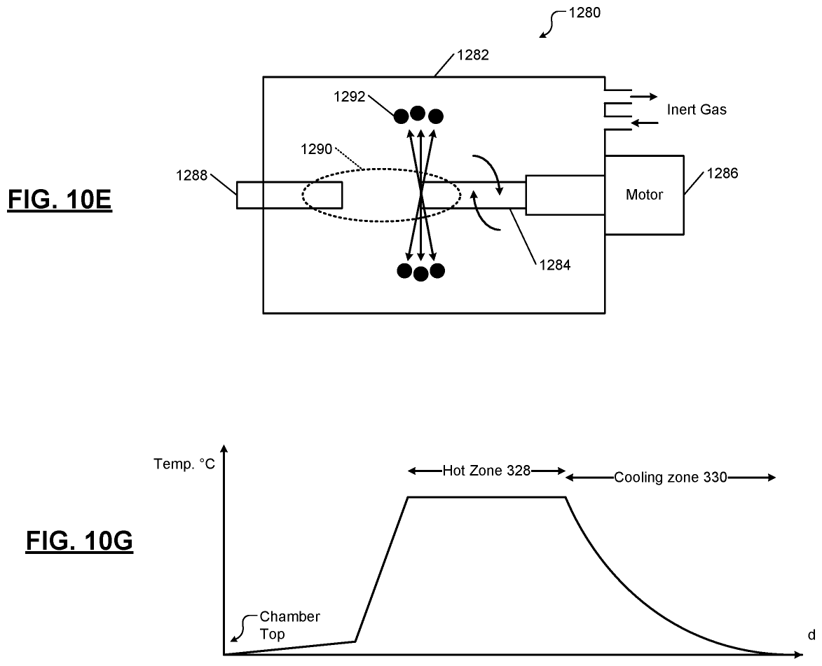

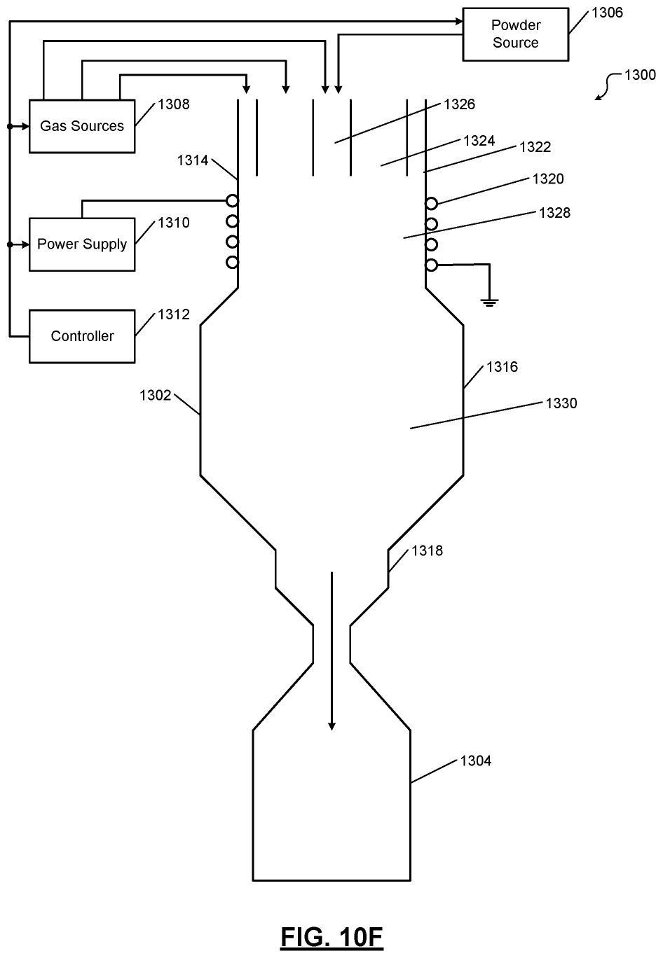

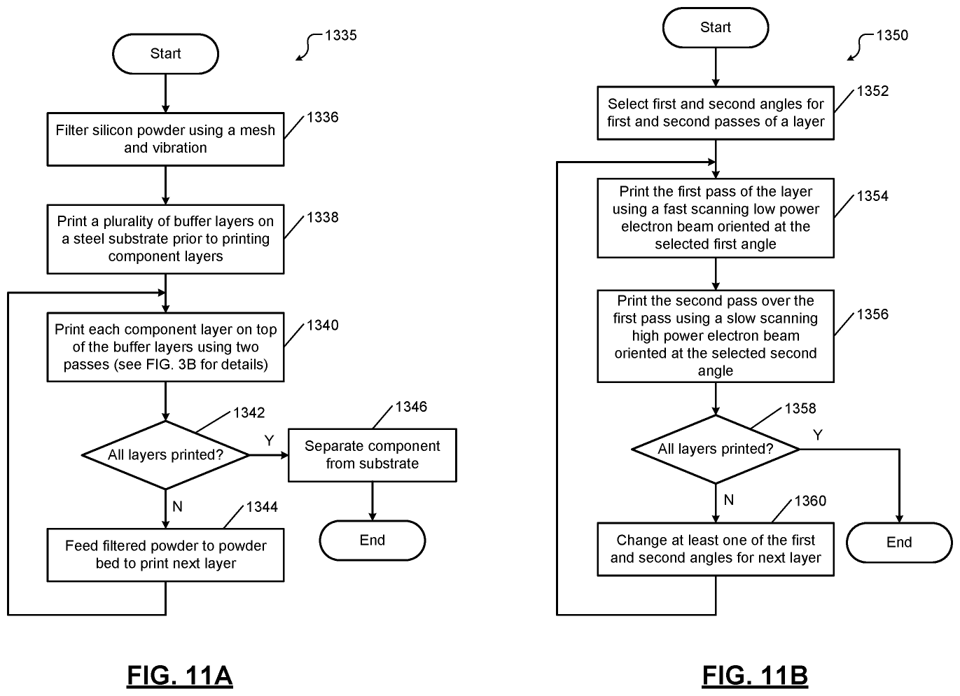

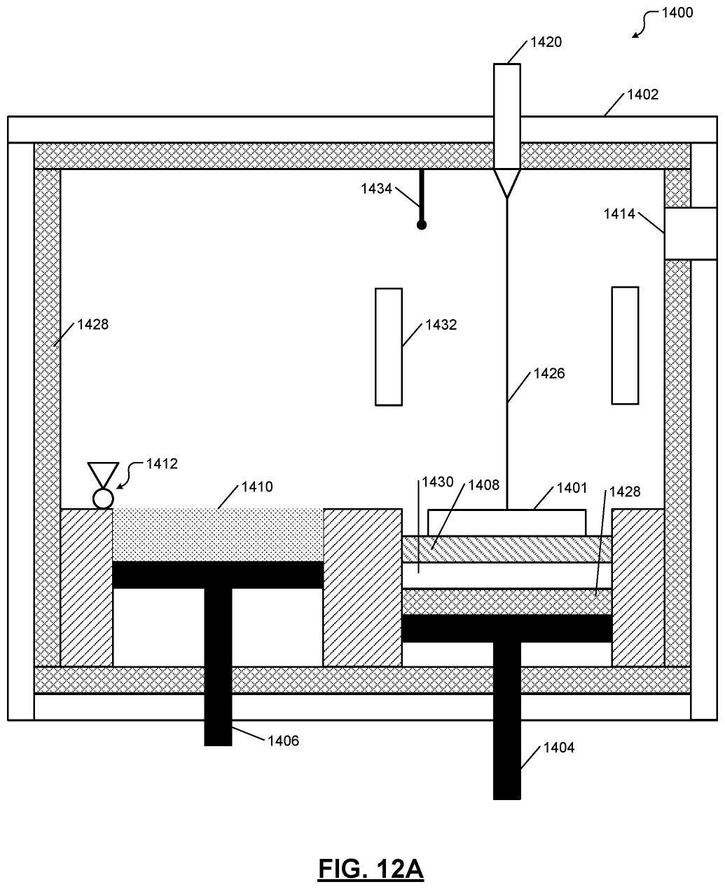

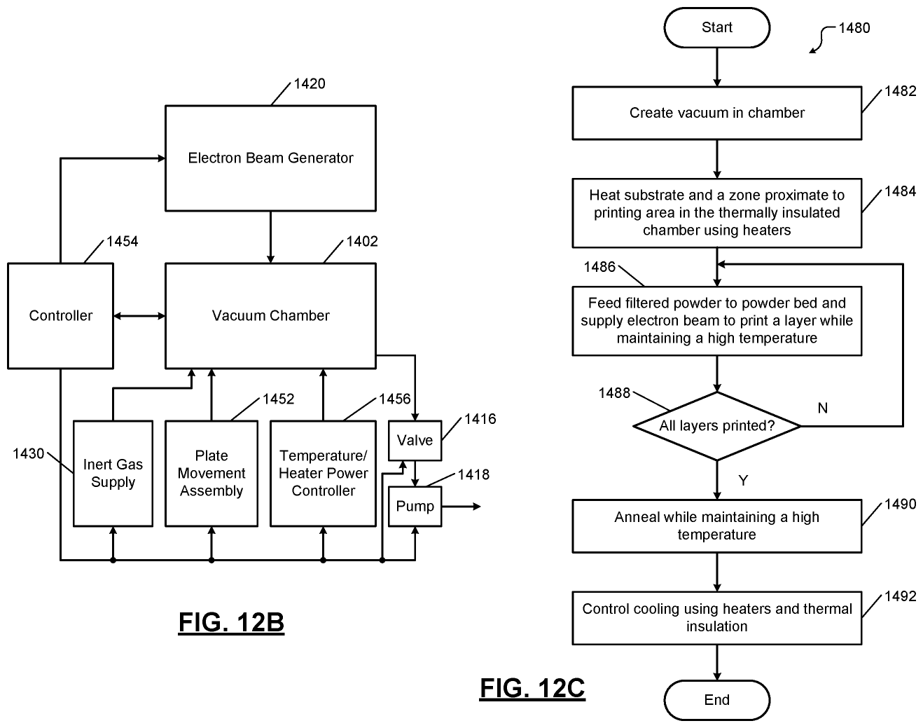

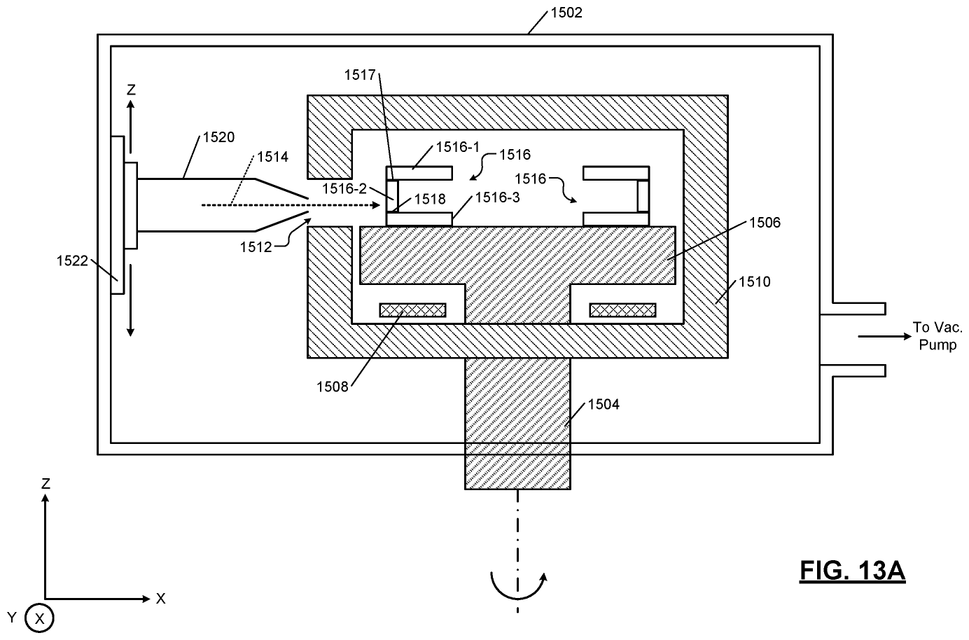

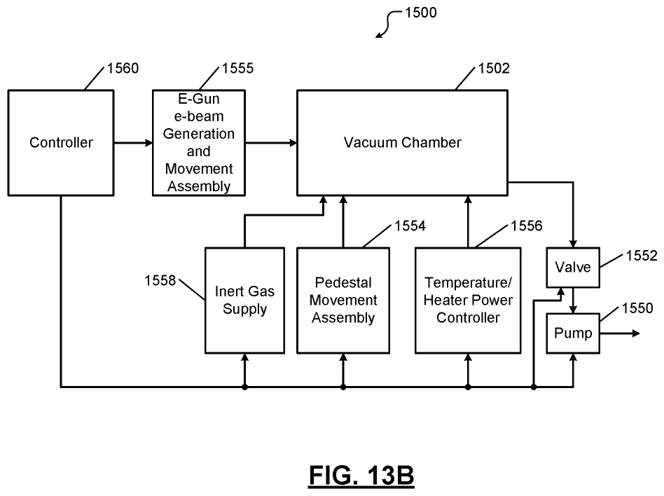

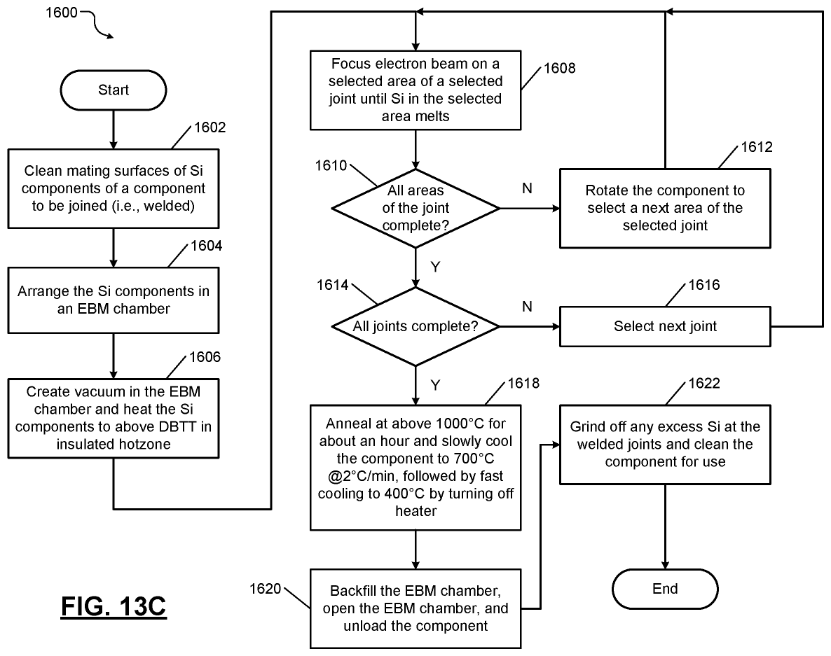

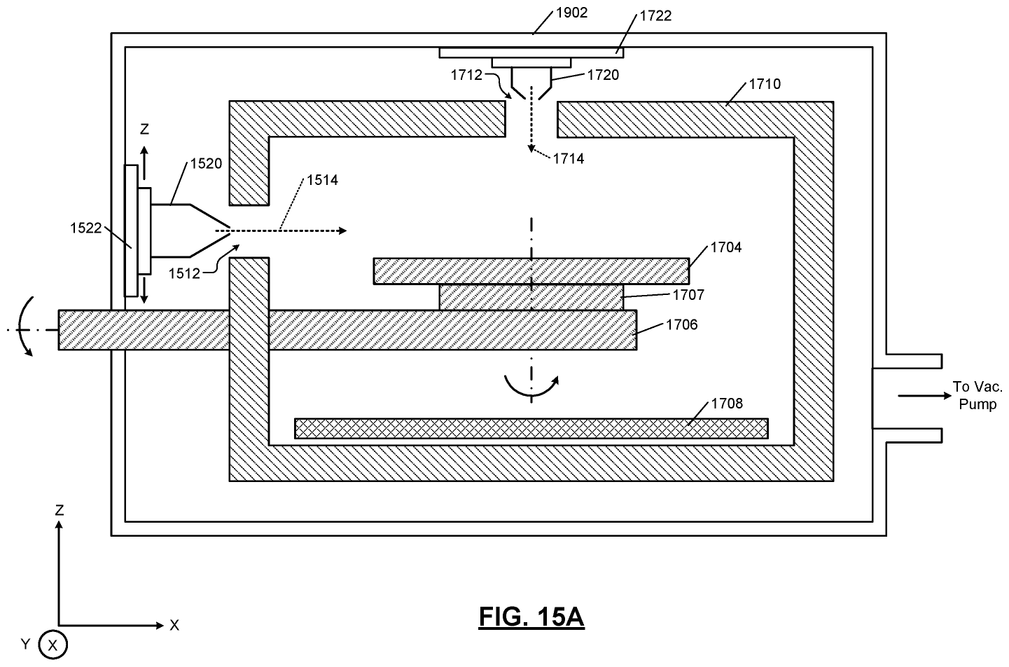

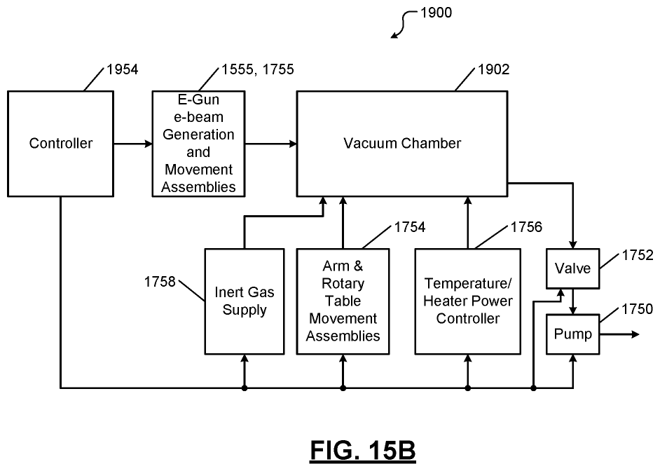

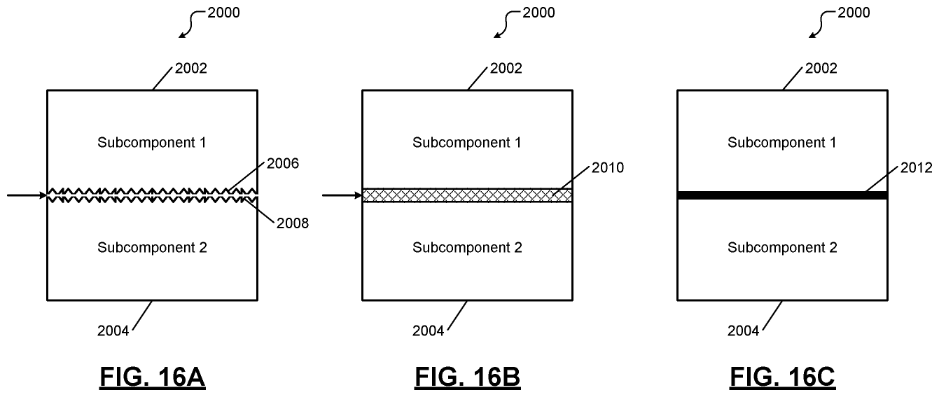

The remainder of the present disclosure is organized as follows. Initially, an example of a substrate processing system including a processing chamber is shown and described with reference to FIG. 9A. An example of an electron beam generator is shown and described with reference to FIG. 9B. Subsequently, an overview of the systems and methods for 3D printing of silicon components according to a fully dense printing method and a crack free printing method is provided. Thereafter, systems and methods for 3D printing of fully dense silicon components according to the fully dense printing methods are described with reference to FIG. 10A-11B. Further, systems and methods for 3D printing of fully dense and crack free silicon components according to the fully dense and crack free methods are described with reference to FIG. 12A-12C. Finally, systems and methods for bonding and repairing silicon components using an electron gun are described with reference to FIGS. 13A-15B. Finally, bonding of two silicon components using the systems and methods of FIGS. 13A-13C, 15A, and 15B resulting in a grain boundary between the two components due mismatched crystalline orientation is shown and described with reference to FIGS. 16A-16C.

FIG. 9A shows an example of a substrate processing system 1100 comprising a processing chamber 1102. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or other processing including etching processes. The system 1100 comprises the processing chamber 1102 that encloses other components of the system 1100 and contains an RF plasma (if used). The processing chamber 1102 comprises an upper electrode 1104 and an electrostatic chuck (ESC) 1106 or other substrate support. During operation, a substrate 1108 is arranged on the ESC 1106.

For example, the upper electrode 1104 may include a gas distribution device 1110 such as a showerhead that introduces and distributes process gases. The gas distribution device 1110 may include a stem portion including one end connected to a top surface of the processing chamber 1102. A base portion of the showerhead is generally cylindrical and extends radially outwardly from an opposite end of the stem portion at a location that is spaced from the top surface of the processing chamber 1102. A substrate-facing surface or faceplate of the base portion of the showerhead includes a plurality of holes through which vaporized precursor, process gas, or purge gas flows. Alternately, the upper electrode 1104 may include a conducting plate, and the process gases may be introduced in another manner.

The ESC 1106 comprises a baseplate 1112 that acts as a lower electrode. The baseplate 1112 supports a heating plate 1114, which may correspond to a ceramic multi-zone heating plate. A thermal resistance layer 1116 may be arranged between the heating plate 1114 and the baseplate 1112. The baseplate 1112 may include one or more channels 1118 for flowing coolant through the baseplate 1112.

If plasma is used, an RF generating system 1120 generates and outputs an RF voltage to one of the upper electrode 1104 and the lower electrode (e.g., the baseplate 1112 of the ESC 1106). The other one of the upper electrode 1104 and the baseplate 1112 may be DC grounded, AC grounded, or floating. For example only, the RF generating system 1120 may include an RF generator 1122 that generates RF power that is fed by a matching and distribution network 1124 to the upper electrode 1104 or the baseplate 1112. In other examples, the plasma may be generated inductively or remotely.

A gas delivery system 1130 includes one or more gas sources 1132-1, 1132-2, . . . , and 1132-N (collectively gas sources 1132), where N is an integer greater than zero. The gas sources 1132 are connected by valves 1134-1, 1134-2, . . . , and 1134-N (collectively valves 1134) and mass flow controllers 1136-1, 1136-2, . . . , and 1136-N (collectively mass flow controllers 1136) to a manifold 1140. A vapor delivery system 1142 supplies vaporized precursor to the manifold 1140 or another manifold (not shown) that is connected to the processing chamber 1102. An output of the manifold 1140 is fed to the processing chamber 1102.

A temperature controller 1150 may be connected to a plurality of thermal control elements (TCEs) 1152 arranged in the heating plate 1114. The temperature controller 1150 may be used to control the plurality of TCEs 1152 to control a temperature of the ESC 1106 and the substrate 1108. The temperature controller 1150 may communicate with a coolant assembly 1154 to control coolant flow through the channels 1118. For example, the coolant assembly 1154 may include a coolant pump, a reservoir, and one or more temperature sensors (not shown). The temperature controller 1150 operates the coolant assembly 1154 to selectively flow the coolant through the channels 1118 to cool the ESC 1106. A valve 1156 and pump 1158 may be used to evacuate reactants from the processing chamber 1102. A system controller 1160 controls the components of the system 1100.

As can be appreciated, the components used in substrate processing systems and processing chambers (e.g., showerheads) need to be manufactured with high precision. Some of these components are made of metals while others are made of materials such as silicon and ceramics. As explained below, 3D printing of components made of materials such as silicon and ceramics is very challenging due to their brittle nature which causes cracks using conventional 3D printing systems, and the present disclosure provides a solution for addressing the challenges and for 3D printing of fully dense and crack free components made of materials such as silicon and ceramics.

Before explaining the fully dense printing method and the crack free printing method of the present disclosure, a brief overview of electron beam melting (EBM) used in these printing methods is provided for completeness. EBM is a type of additive manufacturing or 3D printing process. A raw material in powder form is placed under a vacuum and is fused together into a solid mass using an electron beam as a heat source. Components can be manufactured by melting the powder layer by layer with the electron beam in a chamber under high vacuum. Since printing is performed at high-vacuum environment, a contamination-free work zone is provided. Additionally, using vacuum makes the process suitable for printing components of reactive materials as well (e.g., materials with a high affinity for oxygen; e.g., titanium). For the electrons to interact, the powder needs to be conductive. At temperatures >450° C., silicon becomes a good conductor. Molten silicon is also a good conductor. Therefore, EBM can be used to print silicon components using the methods of the present disclosure described below.

FIG. 9B schematically shows an example of an electron beam generator (also called an electron gun) 1170 that is connected to a vacuum chamber 1172. Detailed examples of the vacuum chamber and other elements used with the printing methods of the present disclosure are shown and described with reference to FIGS. 10A-12C. FIG. 9B focuses on the electron gun. The electron gun 1170 comprises a tungsten filament 1174 that is heated in a vacuum to produce electrons. Using a focus coil 1176 and a deflection coil 1178, the electrons are accelerated and projected as an electron beam 1179 on a layer of powder 1180 deposited on a build plate 1182. The electrons in the electron beam 1179 heat and melt the layer of powder 1180 to build a component layer by layer. A plate movement assembly 1184 lowers the build plate 1182 as the layers of the component are built. A vacuum pump 1186 maintains a high vacuum in the vacuum chamber 1172. For example, the pressure in the vacuum chamber 1172 can be <1E-5 Torr, which is the same as <0.01 mTorr or <1.33 mPa. A power supply 1188 supplies power to the filament 1174 and the focus and deflection coils 1176, 1178. A controller 1190 controls the power supply 1188, the vacuum pump 1186, and the plate movement assembly 1184.

Briefly, in the fully dense printing method, the present disclosure describes systems and methods for printing fully dense silicon components using 3D printing technology (i.e., additive manufacturing). The 3D printing technology of the present disclosure is powder bed based electron beam melting (EBM) that uses an electron beam to melt silicon powder on a build plate (i.e., a building platform or a substrate) in a vacuum chamber. Unlike 3D printing of metal-based materials, the systems and methods of the present disclosure address factors that affect printing quality when printing fully dense silicon components. The present disclosure describes particle morphology, size, and distribution of silicon powder and also describes a printing strategy, an appropriate electron beam power and printing speed, and a powder bed preheating strategy. All of these techniques contribute to printing fully dense silicon components using 3D printing. The systems and methods of the present disclosure can print large silicon components with complex internal features which cannot be accomplished using traditional subtractive machining methods.

Additionally, in the crack free printing method, the present disclosure describes a design of a 3D printing equipment with a low temperature gradient. The design uses one or multiple heaters along with good thermal insulation in a vacuum chamber to minimize a temperature gradient during printing of a silicon component, in-situ annealing, and cooling. Using the heaters and the insulation, a uniform high temperature with a low thermal gradient is maintained throughout the equipment and throughout the printing process. The heaters can be either resistive or inductive heaters, IR lamp radiation heaters, or blue light heaters (e.g., using blue LEDs). The insulation material can be rigid carbon fiber insulation, soft graphite felt, or a combination of both. Due to high reactivity of carbon and melted silicon with oxygen at elevated temperatures, the equipment needs to be vacuum tight. Silicon is preferably printed in a vacuum chamber under high vacuum.

The low thermal gradient method according to the crack free printing method can be used for powder bed based printing methods. Due to the brittle nature of silicon materials, the substrate temperature for 3D printing is preferably greater than the ductile to brittle transition temperature (DBTT) of silicon (e.g., >1000° C.) during printing and annealing of the silicon component to prevent thermal stress buildup. This way, silicon is ductile during printing. The printed component is also preferably cooled slowly at a controlled rate.

In the low thermal gradient method according to the crack free printing method, silicon is a preferred substrate for 3D printing of silicon components to avoid a mismatch of coefficient of thermal expansion (CTE), which can occur if non-silicon substrates are used, and which can lead to component cracking. Silicon is the preferred substrate over substrates of other material such as metals for an additional reason: to prevent contamination due to impurity diffusion from the non-silicon material into silicon, which can occur at high temperatures using during printing and annealing. Accordingly, using the crack free method of the present disclosure, silicon components with high purity and low thermal stress (e.g., crack free) can be printed. The crack free printing methodology of the present disclosure can be applied to other brittle materials such as alumina, silicon carbide, ceramics, and so on.

More specifically, the fully dense printing method addresses the following concerns for 3D printing of silicon. Current additive manufacturing technology for silicon is based on direct energy deposition (DED). Voids or pores exist in the printed silicon samples due to insufficient laser energy density or strong spatter ejection in the current laser-based printing process.

Accordingly, the fully dense printing method of the present disclosure describes using a steel substrate since a silicon substrate can crack and chip due to the thermal impact applied to the substrate during printing. The cracks can propagate in Z direction which may fracture the printed sample. A steel substrate is used to avoid the damage to the printed silicon sample. Since the melting point of steel is higher than that of silicon, steel does not melt during silicon printing.

Additionally, in the fully dense printing method, a plurality of buffer layers of silicon are initially printed on the steel substrate, and then layers of silicon for the actual component are printed on top of the buffer layers. The buffer layers are printed at a faster rate than the rate at which the subsequent silicon layers are printed on the buffer layers to print the component. This reduces a coefficient of thermal expansion (CTE) mismatch between the steel substrate and the silicon layers printed on the buffer layers. Without the buffer layers, a large CTE mismatch can exist between the steel substrate and the silicon layers printed directly on the steel substrate to manufacture a component, which can lead to fracture in the printed component. The buffer layers reduce CTE mismatch that can occur between the steel substrate and the silicon layers printed to build the component if the layers are printed directly on the steel substrate without the intervening buffer layers.

Further, in the fully dense printing method, the silicon layers are printed on the buffer layers using a double printing method as follows. Each silicon layer printed on the buffer layer is printed twice (i.e., using two passes). In a first printing or pass, the layer is printed at a faster speed (i.e., with a shorter exposure time of the electron beam) using a lower power electron beam than the speed and power used in a second printing or pass. During the first printing, the lower power does not fully melt the silicon but binds the silicon particles together. Subsequently, during the second printing, the slower speed and higher power of the electron beam scanning the material from the first pass with a longer exposure time fully melts the already bonded silicon particles from the first pass, thus forming a fully dense layer of silicon. Thus, the first printing pass can be called a sintering pass, and the second printing pass can be called a melting pass.

Furthermore, in each layer, the orientation of the electron beam in the first pass can be different than in the second pass to even out thermal stress in each layer. For example, suppose three layers A, B, and C are to be printed, and each layer is printed using two passes P1 and P2. Let m and n respectively denote the angle or orientation of the electron beam in degrees during passes P1 and P2 in the X-Y plane along the substrate. For layer A, (m, n)=(0, 90); for layer B, (m, n)=(45, −45); and for layer C, (m, n)=(90, 0). The pattern is repeated for subsequent layers. This effectively reduces thermal stress across the layers and prevents the cracking in the printed component.

The double printing method of the first solution also reduces spatter ejection, which typically involves bright (melted airborne) particles of silicon blown away from the melting pool due to an inert gas typically flowing at the bottom of the printing chamber.

These particles cool down in flight and land on the downwind printed sample. These particles might not be fully melted during the printing of the next layer, which can cause voids or porosity in the component printed using traditional printing methods. In contrast, in the double printing method of the present disclosure, the spatter is significantly reduced since vacuum is used (i.e., no inert gas is used) during printing. Nonetheless, if any spatter occurs, the first printing pass binds these ejected particles to each other and to the silicon particles, which are then fully melted during the second printing pass. Further, since a lower power electron beam is used during the first pass, the amount of spatter ejection is reduced, and whatever spatter ejection occurs during the first pass is fully melted during the second pass.

Furthermore, any spatter ejection occurring during the second pass is also fully melted due to the use of a slow high power electron beam. Specifically, the area recently printed is still hot enough to melt any ejected particles landing in the area. Additionally, if any ejected particles land in the area to be printed, these particles are fully melted by the high power electron beam as printing continues and reaches the area. Thus, a fully dense component without porosity is manufactured using the double printing method.

In the fully dense printing method, before printing, the silicon powder is preferably filtered (i.e., sorted) using a mesh to obtain particles having size in a relatively narrow range. For example only, the range can be 40-100 μm. As another example, the range can be 50-90 μm. This ensures that the particles have spherical shape and smooth surface and that there is no particle aggregation. That is, the filtered powder flows and spreads better in the powder bed on the substrate than the unfiltered powder. When the gas atomized unfiltered powder is poured in the mesh for filtering, the filter size of the mesh is selected, and the mesh is vibrated mechanically. For example, the mesh can be vibrated mechanically or using ultrasound.

After printing, the component is separated from the steel substrate by cutting through the buffer layer, for example. The buffer layers are relatively easy to cut through, which is an additional benefit of using the buffer layers. The separated steel substrate can be refinished and prepared to receive new buffer layers to manufacture a next component.

In the fully dense printing method, due to the use of the buffer layers and the double printing method, a large CTE mismatch between the steel substrate and the printed silicon is reduced and voids in the printed silicon are eliminated. For example, while a few initial layers are being printed on the buffer layers, the buffer layers reduce CTE mismatch between the steel substrate and the layers being printed, which prevents fracturing of the printed silicon. However, a large thermal stress still exists in the printed silicon samples whenever using the fully dense printing method in the conventional metal 3D printers which do not have a high temperature hot zone. All the printed silicon samples in the conventional metal 3D printers have micro-cracks with no exception.

To eliminate the micro-cracks in the printed silicon, a new 3D printing equipment design with a low temperature gradient is described in the present disclosure. The design uses a vacuum chamber with one or multiple heaters along with good thermal insulation to minimize the temperature gradient during Si part printing, in-situ annealing, cooling. The heaters can be either resistive or inductive heaters, IR lamp radiation heaters, or blue light heaters (e.g., using blue LEDs). The insulation materials can be either rigid carbon fiber insulation or soft graphite felt or combination of both. Because of high reactivity of carbon and Si melt with oxygen at elevated temperatures, the system is enclosed in a vacuum tight environment. For example, the printing is carried out in a vacuum chamber. The low thermal gradient method can be used for powder bed based printing method.

Due to the brittle nature of silicon materials, the substrate temperature for 3D printing is preferably greater than the DBTT of silicon (e.g., >1000° C.) during printing and annealing of the silicon component to prevent thermal stress buildup. The printed component is also cooled slowly. A silicon substrate is preferred for printing silicon components to avoid CTE mismatch. The methodology can be applied to other brittle materials, such as silicon carbide (SiC), ceramics, alumina, and so on.

The new 3D printing equipment is designed for printing brittle materials, such as silicon, silicon carbide, alumina, and other ceramics. Presently, the conventional 3D printing equipment is designed for printing metals which are ductile materials and are more tolerant to thermal stress. Therefore, ex-situ annealing can be used to reduce thermal stress. However, the current 3D printing equipment is not capable of uniformly heating and maintaining high substrate temperatures (e.g., >600° C.), and large temperature gradient occurs while printing silicon components, where melt pool temperature is >1414° C., which is the melting point of silicon. In addition, the cool down in the currently used 3D printing processes is fast and not controlled. The large temperature gradient during printing and cooling down of silicon components leads to micro-cracks in all 3D-printed silicon samples using the conventional metal 3D printers (either powder bed or powder fed printing, with or without buffer layers). No crack free printed silicon samples have been observed using 3D metal printers. The micro-cracks cannot be healed in ex-situ annealing.

Accordingly, the crack free printing method of the present disclosure describes using one or multiple heaters along with good thermal insulation to minimize the temperature gradient during Si printing, in-situ annealing, and cooling. The heaters can be either resistive or inductive heaters, IR lamp radiation heaters, or blue light heaters (e.g., using blue LEDs). The insulation materials can be either rigid carbon fiber insulation or soft graphite felt or combination of both. Because of high reactivity of carbon and Si melt with oxygen at elevated temperatures, the system uses a vacuum tight chamber. For example, silicon components are printed in a vacuum chamber.

As described below with reference to FIGS. 12A-12C, according to the crack free printing method, the chamber can be rectangular with rigid insulation plates covering the inside at top and bottom, left and right, front and back. Alternatively, the chamber can be cylindrical with rigid insulation plates covering the inside at top and bottom and a rigid insulation cylinder shielding the surrounding cylindrical wall. The insulation plates and cylinder can also be made of multiple layers, such as rigid insulation/rigid insulation, graphite/rigid insulation, rigid insulation/felt, graphite/felt, carbon fiber composite (CFC)/felt. Felt is essentially a cloth-like soft material made of many layers of carbon fiber. Felt prevents heat from escaping and helps in maintaining the high temperature uniform throughout the printing process (i.e., felt helps in maintaining a low thermal gradient throughout the printing process).

In the crack free silicon printing method, graphite resistive heaters are preferred and schematically laid out as shown in FIGS. 12A-12C described below. One or more graphite susceptors (i.e., shields) could be placed inside the side heaters to protect the heaters. The silicon powder is dosed by a powder wiper after completion of each layer of printing. When the printing of all layers is completed, the printed samples are embedded into silicon powder. Silicon powder has low thermal conductivity and reduces heat transfer between the printed components.

Due to the brittle nature of silicon materials, the substrate temperature is preferred to be greater than the DBTT point of silicon (e.g., >1000° C.) during printing of the silicon component (so that silicon is ductile during printing) and during annealing to prevent thermal stress buildup. The annealing temperatures are preferably between 1100-1200° C. The cool down is preferably at a rate <5° C./min from annealing temperature to 400° C. and is followed by backfill of an inert gas (e.g., Ar). The substrate for 3D printing Si is preferably made of Si materials to avoid CTE mismatch and contaminations. The methodology can be used to print components of other brittle materials such as ceramics, silicon carbide, alumina, and so on.

Accordingly, by using heaters and insulation, the crack free printing method of the present disclosure maintains a low temperature gradient during printing and in-situ annealing as well as provides a slow cool down at a controlled rate, which significantly reduces thermal stress and eliminates micro-cracking in the printed Si components. In contrast, the conventional metal 3D printing equipment is not capable of maintaining temperatures above 600° C. and controlled cool down, which induces high thermal stress and causes micro-cracks in the printed Si part and renders it useless. Further, unlike the conventional metal 3D printing equipment, the printing method of the present disclosure uses a high vacuum chamber and graphite based heaters and carbon fiber based thermal insulations to minimize the temperature gradient during printing, annealing and cool down.

These and other features of the present disclosure are now described below in details. FIGS. 10A-11B show the systems and methods according to the fully dense printing method of the present disclosure. FIGS. 12A-12C show the system and method according to the crack free printing method of the present disclosure.

FIG. 10A shows a system 1200 for 3D printing a component 1201 of a nonmetallic material such as silicon on a metal substrate according to the fully dense printing method of the present disclosure. The system 1200 comprises a vacuum chamber 1202. The vacuum chamber 1202 comprises a first plate 1204 and a second plate 1206. The first plate 1204 supports a substrate 1208 on which a component is printed. Accordingly, the first plate 1204 is also called a building plate, a building platform, a printing plate, or another suitable name.

The second plate 1206 stores the nonmetallic material 1210 (e.g., silicon powder). A dose bar or a powder wiper 1212 supplies the nonmetallic material 1210 to the substrate 1208 prior to printing each layer. Accordingly, the second plate 1206 is also called a feeding plate, a dosing plate, or another suitable name.

The vacuum chamber 1202 comprises an observation window 1214. The observation window 1214 is coated with a film to reduce heat dissipation. The system 1200 further comprises an electron beam generator 1220 that projects an electron beam 1226 onto the substrate 1208 during printing. For example, the electron beam generator 1220 is similar to the electron beam generator 1170 shown in FIG. 9B. Accordingly, the electron beam generator 1220 is not described in detail for brevity.

FIG. 10B shows additional elements of the system 1200. The system 1200 further comprises an inert gas supply 1230 to supply the inert gas to backfill the vacuum chamber 1202 after the printing is finished and before opening the vacuum chamber 1202. The system 1200 further comprises a plate movement assembly 1232 to move the first plate 1204 downwards and to move the second plate 1206 upwards during printing. The system 1200 further comprises a vacuum pump 1218 that is connected to the vacuum chamber 1202 via a valve 1216 to maintain a high vacuum in the vacuum chamber 1202. For example, the pressure in the chamber 1202 can be <1E-5 Torr, which is the same as <0.01 mTorr or <1.33 mPa. The system 1200 further comprises a controller 1234 that controls all the elements of the system 1200 as explained below.

For example, the system 1200 uses an electron beam melting (EBM) printing technology based printer and silicon powder manufactured by plasma rotating electrode processing (PREP, described with reference to FIGS. 10D and 10E below) or alternatively by inductively coupled thermal plasma (ICTP, described with reference to FIGS. 10F and 10G) to print silicon in a layer by layer manner. For example, a diameter of a focus spot of the electron beam 1426 may be 70 μm. The electron beam energy is delivered to a focus plane (i.e., the horizontal plane of the top surface of the build plate 1204) via a point-by-point exposure methodology.

FIG. 10C schematically shows how the electron beam 1226 delivers energy on the focus plane (the build plate 1204). Each circle shown is a schematic projection of the electron beam 1226 on the focus plane and may have a diameter of 70 μm, for example. The electron beam 1226 dwells on each circle for a short time called an exposure time and then moves to a horizontally neighboring circle (next column) in a row. The moving distance is called a point distance (e.g., 80 μm) as shown in FIG. 10C.

After completing the row, the electron beam 1226 moves to a next row. This moving distance is called a hatch distance (e.g., 60 μm) as shown in FIG. 10C. The melting of silicon powder in each circle occurs when the electron beam 1226 is dwelling on the circle (within the exposure time). In this process, depending on the electron beam power and the exposure time, the electron beam 1226 creates a melting pool of silicon whose size is approximately 1.5-2 times the size of the circle and is about 2-3 layers deep. Therefore, the silicon powder particles are well covered by the melting pool so that they can be melted as the electron beam 1226 scans in the X-Y plane. The combination of electron beam power, exposure time, the point distance, and the hatch distance determines the energy density of the 3D printing. As this process continues, all the selected silicon powder in this layer is melted. The process continues until all the layers are completed.

In the present disclosure, the 3D printing of silicon is controlled from aspects of silicon powder, printing strategy, and thermal stress as follows. The silicon powder is manufactured via plasma rotating electrode processing (PREP) or inductively coupled thermal plasma (ICTP) method which produces silicon powder with highly spherical, dense, doped silicon particles, and which are described with reference to FIGS. 10D-10G below. Each individual silicon particle has a smooth surface and does not have particle aggregation. For example, the particle size ranges between 40-100 μm. As another example, the particle size can range between 50-90 μm.

FIG. 10D shows an example of a system 1250 for selecting silicon powder from a stock of silicon powder manufactured using PREP. The system 1250 comprises a feeder 1252 that feeds the stock of silicon powder manufactured using PREP, which is described with reference to FIG. 10E below. The system 1250 comprises a first mesh 1254 arranged vertically above a second mesh 1256. As shown in sections A-A and B-B of the first and second meshes 1254, 1256, the holes of the first mesh 1254 have a diameter d1 that is greater than a diameter d2 of the holes of the second mesh 1256.

The feeder 1252 feeds the stock of the silicon powder manufactured using PREP into the first mesh 1254. A vibrating system 1258 vibrates the first and second meshes 1254, 1256. For example, the vibrating system 1258 may vibrate the first and second meshes 1254, 1256 mechanically or using ultrasound. At the end of the sieving process carried out by the vibration, silicon powder having particles with diameters between d1 and d2 remain in the second mesh 1256, which are used as the nonmetallic material 1210 for printing the component 1201.

For example, the holes of the first mesh 1254 may be of the size 88 μm, the holes of the second mesh 1256 may be of the size 53 μm. The first mesh 1254 screens out too big particles (e.g., of size >88 μm). The second mesh 1256 screens out too small particles (e.g., of size <53 μm). The powder left in the second mesh 1256 is collected for printing. The particles in the collected powder flow smoothly without clogging the powder supply hose (not shown).

In general, it is understood that the mesh sizes can be selected depending on the particle sizes desired. For example, if the particle size is desired to be between x and y μm, where y>x, the diameter d1 of the first mesh 1254 should be y or more (i.e., d1≥y), and the diameter d1 of the first mesh 1254 should be y or more (i.e., d1≤x).

Accordingly, the two mesh solution may be used without constraints on how the powder stock is manufactured (i.e., the stock need not be manufactured using PREP). The single mesh solution may be used with atomized powder feed stock when any particle size less than the diameter of the mesh holes is acceptable. In general, using either solution, silicon powder having size in a relatively narrow range (e.g., 40-100 μm) can be selected for printing. As another example, using either solution, silicon powder having size in a range of 50-90 μm can be selected for printing.

FIG. 10E shows a system 1280 for manufacturing powder of a material such as silicon using the plasma rotating electrode processing (PREP) method. The system 1280 comprises a chamber 1282. An inert gas is circulated through the chamber 1282. An electrode 1284 made of a material of which powder is to be manufactured (e.g., silicon) is coupled to a shaft of a motor 1286. A plasma torch 1288 heats a distal end of the electrode 1284 to strike plasma 1290 as the motor 1286 is rotated. As a result, the distal end of the electrode 1284 melts into molten liquid. The molten liquid is crushed into droplets 1292 that are ejected by the centrifugal force of the rotating electrode 1284. The droplets 1292 solidify into powder. The powder thus manufactured using the PREP method is used as feedstock in the systems and methods of the present disclosure.

FIG. 10F schematically shows a system 1300 for converting an irregular shaped and/or porous, un-doped silicon powder (hereinafter raw silicon powder) to spherical shaped, dense, and doped Si powder (hereinafter fine silicon powder) using atmospheric pressure inductively coupled thermal plasma. The system 1300 comprises a chamber 1302 configured to receive and process various gases and the raw silicon powder and comprises a receptacle 1304 arranged at the bottom of the chamber 1302 to collect the fine silicon powder produced by the chamber 1302. The system 1300 further comprises a source supplying the raw silicon powder (hereinafter the powder source) 1306, a plurality of gas sources 1308 supplying a plurality of gases, a power supply 1310, and a controller 1312. The controller 1312 controls supply of the raw silicon powder from the powder source 1306 to the chamber 1302, supply of gases from the gas sources 1308 to the chamber 1302, and power supplied by the power supply 1310 to the coils 1320.

The chamber comprises an upper portion 1314 having a first cross-sectional area (e.g., a first diameter), a middle portion 1316 having a second cross-sectional area (e.g., a second diameter), and a bottom portion 1318 having a third cross-sectional area (e.g., a third diameter). The third cross-sectional area is less than the first cross-sectional area, and the first cross-sectional area is less than the second cross-sectional area. The upper portion 1314 comprises inlets for receiving the raw silicon powder and the various gases from the powder source 1306 and the gas sources 1308 as described below. A coil 1320 is arranged around the upper portion 1314. The coil 1320 is connected to the power supply 1310. The bottom portion 1318 is funnel shaped and is connected to the receptacle 1304.

The upper portion 1314 comprises three concentric inlets formed by three concentric tubes: an inner tube 1326, a middle tube 1324 coaxially surrounding the inner tube 1326, and an outer tube 1322 defined by an outer wall of the middle tube 1324 and an inner wall of the upper portion 1314. The tubes 1322, 1324, 1326 extend vertically downwards from a top end of the upper portion 1314 to approximately a midpoint of the upper portion 1314. The coil 1320 is arranged around the upper portion 1314 between about the midpoint of the upper portion 1314 and a bottom end of the upper portion 1314.

The raw silicon powder from the powder source 1306 is mixed with a carrier gas (e.g., H₂) supplied by one of the gas sources 1308, and the mixture is supplied to the chamber 1302 through the inner tube 1326. A dopant gas (e.g., B₂H₆ for p-type; and PH₃, AsH₃ for n-type) supplied by one of the gas sources 1308 is supplied to the chamber 1302 through the middle tube 1324. A sheath gas (e.g., an inert gas such as Ar) supplied by one of the gas sources 1308 is supplied to the chamber 1302 through the outer tube 1322. Power is supplied to the coil 1320 by the power supply 1310 to generate an inductively coupled thermal plasma (ICTP). A lower region of the upper portion 1314 surrounded by the coil 1320 is called a hot zone (identified at 1328). The plasma heats and melts the raw silicon powder in the hot zone.

The dopant containing neutral molecules, radicals and ions adsorb and react with the surface of the molten Si particles so that dopant atoms diffuse into the molten Si particles, and H₂ gas desorbs from the surface. The small molten silicon particles become spherical in shape, and any internal voids in the particles bubble out to minimize surface energy. After the spherical molten Si particles fall from the plasma in the hot zone 1328, the spherical molten Si particles solidify and cool down in the middle portion 1316 of the chamber 1302 (identified as a cooling zone 1330) and are collected in the receptacle 1304.

FIG. 10G shows a temperature profile of the process performed in the chamber 1302, where d is the distance measured from the top of the chamber 1302. The final particle size distribution of the Si particles is controlled by the starting particle size distribution, which can be controlled by mesh sizes as described above. The dopant concentration can be controlled by controlling the percentage of the dopant in the carrier gas and a duration for which the Si particles are exposed to the high temperatures produced by the inductively coupled plasma. The duration is a function of the length of the coil 1320, the flow rate of the carrier gas, and gravity.

The plasma is on (i.e., present) mainly in the lower region of the upper portion 1314 surrounded by the coil 1320 (i.e., the hot zone 1328). The plasma is off (i.e., not present) in the cooling zone 1330 (i.e., the middle portion 1316). In the hot zone 1328, individual silicon particle falls into the plasma where it melts, spheroidizes, densifies, and mixes with dopant while falling through the plasma. In the cooling zone 1330, since the plasma is off (i.e., not present), temperature drops, and the particle solidifies and cools down. The duration for doping a particle is the time for which the particle stays in the plasma, which approximately equals the length of the hot zone 1328 (i.e., the height of the lower region of the upper portion 1314 surrounded by the coil 1320) and a speed at which the particle falls through the plasma. The speed is a function of the flow rate of the carrier gas, the temperature of the hot zone 1328, and gravity.

The ICTP method is better than the PREP method in many respects. The porous and/or irregular shaped (i.e., the raw) silicon powder used in the ICTP method is typically mass produced without dopants and can be purchased at very low price comparing to solid silicon electrodes used in the PREP method. The ICTP method of converting the raw silicon powder into the fine spherical shaped powder described above is more cost effective than the PREP method, which converts silicon electrode to spherical shaped powder.

The particle size distribution (PSD) of a powder or granular material such as the powder manufactured using the PREP or ICTP method described above is a list of values or a mathematical function that defines the relative amount, typically by mass, of particles present according to size. The most common method of determining PSD is sieve analysis where powder is separated on sieves of different sizes (e.g., as described with reference to FIG. 10D above). Thus, the PSD is defined in terms of discrete size ranges: for example, “% of sample between 45 μm and 53 μm”, when sieves of these sizes are used. The PSD is usually determined over a list of size ranges that covers nearly all the sizes present in the sample. Some methods of determination allow much narrower size ranges to be defined than can be obtained by using sieves, and are applicable to particle sizes outside the range available in sieves. However, the notion of a sieve that retains particles above a certain size and passes particles below that size is commonly used in presenting PSD data.

The PSD may be expressed as a range analysis in which the amount in each size range is listed in order. The PSD may also be presented in cumulative form in which the total of all sizes retained or passed by a single notional sieve is given for a range of sizes. Range analysis is suitable when a particular ideal mid-range particle size is being sought while cumulative analysis is used where the amount of under-size or over-size is to be controlled.

Before a PSD can be determined, a representative sample is obtained. In the case where the material to be analyzed is flowing, the sample is withdrawn from the stream in such a way that the sample has the same proportions of particle sizes as the stream. Preferably many samples of the whole stream are taken over a period instead of taking a portion of the stream for the whole time. After sampling, the sample volume typically needs to be reduced. The material to be analyzed is blended and the sample is withdrawn using techniques that avoid size segregation (e.g., using a rotary divider).

Various PSD measurement techniques may be used to measure the particle size of the silicon powder used in the systems and methods of the present disclosure. Some examples of the PSD measurement techniques are described below. For example, sieve analysis is a simple and inexpensive technique. Sieve analysis methods may include simple shaking of the sample in sieves until the amount retained becomes more or less constant. This technique is well-suited for bulk materials.

Alternatively, materials can be analyzed through photo-analysis procedures. Unlike sieve analyses which can be time-consuming and sometimes inaccurate, taking a photo of a sample of the materials to be measured and using software to analyze the photo can result in rapid, accurate measurements. Another advantage is that the material can be analyzed without being handled.

In other examples, PSDs can be measured microscopically by sizing against a graticule and counting. For a statistically valid analysis, millions of particles are measured. Automated analysis of electron micrographs is used to determine particle size within the range of 0.2 to 100 μm.

Coulter counter is an example of electro-resistance counting methods that can measure momentary changes in conductivity of a liquid passing through an orifice that take place when individual non-conducting particles pass through. The particle count is obtained by counting pulses. This pulse is proportional to the volume of the sensed particle. Very small sample aliquots can be examined using this method.

Other examples include sedimentation techniques. These techniques are based on study of terminal velocity acquired by particles suspended in a viscous liquid. These techniques determine particle size as a function of settling velocity. Sedimentation time is longest for the finest particles. Accordingly, this technique is useful for sizes below 10 μm. Sub-micrometer particles cannot be reliably measured due to the effects of Brownian motion. A typical measuring apparatus disperses the sample in liquid, then measures the density of the column at timed intervals. Other techniques determine the optical density of successive layers using visible light or x-rays.

Laser diffraction methods depend on analysis of the halo of diffracted light produced when a laser beam passes through a dispersion of particles in air or in a liquid. The angle of diffraction increases as particle size decreases. Accordingly, this method is particularly good for measuring sizes between 0.1 and 3,000 μm. Due to advances in data processing and automation, this is the dominant method used in industrial PSD determination. This technique is relatively fast and can be performed on very small samples. This technique can generate a continuous measurement for analyzing process streams. Laser diffraction measures particle size distributions by measuring the angular variation in intensity of light scattered as a laser beam passes through a dispersed particulate sample. Large particles scatter light at small angles relative to the laser beam and small particles scatter light at large angles. The angular scattering intensity data is then analyzed to calculate the size of the particles responsible for creating the scattering pattern using the Mie theory or Fraunhofer approximation of light scattering. The particle size is reported as a volume equivalent sphere diameter.

In laser obscuration time (LOT) or time of transition (TOT) method, a focused laser beam rotates at a constant frequency and interacts with particles within the sample medium. Each randomly scanned particle obscures the laser beam to a dedicated photo diode, which measures the time of obscuration. The time of obscuration t directly relates to the particle's diameter D by the equation D=V*t, where V is the beam rotation velocity.

In acoustic spectroscopy or ultrasound attenuation spectroscopy, ultrasound is used instead of light to collect information on the particles that are dispersed in fluid. The dispersed particles absorb and scatter ultrasound. Instead of measuring scattered energy versus angle, as with light, in the case of ultrasound, measuring the transmitted energy versus frequency is a better choice. The resulting ultrasound attenuation frequency spectra are the raw data for calculating particle size distribution. It can be measured for any fluid system with no dilution or other sample preparation. Calculation of particle size distribution is based on theoretical models that are well verified for up to 50% by volume of dispersed particles. As concentration increases and the particle sizes approach nanoscale, conventional modelling need to include shear-wave re-conversion effects to accurately reflect the real attenuation spectra.

After the silicon powder produced by the PREP or ICTP system shown in FIGS. 10E and 10F is sieved using the system shown in FIG. 10D, the PSD of the silicon particles is determined using one or more of the PSD measurement techniques described above. The powder selected for use in the systems and methods of the present disclosure is denser and more spherical. For example, 90 wt. % of the powder has the particle size in the range of 40-100 μm (or, in another example, in the range of 50-90 μm), defined as volume-based particle size D=2*[3*V/(4*π)]\hat{ }(1/3)). While the term sphere or spherical is used to describe the particles' shape, at least 90% particles have a volume-based particle size that is not more than 5% less than the measured longest diameter (measured using a microscope).

A silicon substrate can fracture and chip due to thermal impact during printing. The cracks can propagate in z direction, which may break the printed component 1201. Therefore, a steel substrate 1208 is used to avoid the damage that can occur to the printed component when the silicon substrate is used to print the silicon component. The melting point of steel is higher than that of silicon and therefore does not melt during silicon printing. Steel is only one example for the substrate material; many other metals, alloys, and non-brittle materials can be used instead as the substrate 1208 so long as the melting point of the material used for the substrate is greater than the melting point of silicon (or of the nonmetallic material 1210 used to print the component 1201).

An energy density of the electron beam is computed to define the intensity of the electron beam energy. Specifically, the energy density is equal to (Electron beam power x Exposure time)/(Point distance×Hatch distance). This equation gives the 2D energy density without considering the layer thickness of the powder and defines the intensity of the electron beam energy in the X-Y plane.

In the present disclosure, the layer thickness is set to such a value (e.g., 30 μm) that only 2D energy density is needed to calculate the intensity of the electron beam energy. Too low of an energy density can lead to a small size of a melted pool that is unable to melt all the powder particles in a layer. The un-melted silicon powder creates discontinuous melting pools during cooling, which increases the surface roughness and pores in the current layer. This occurs when the energy density is less than 5 μJ/μm², for example.

As the energy density increases, the size of the melting pool increases, and the melted droplets have better flowability. The printed component has less pores, and the relative density of the printed component increases. This corresponds to energy density level between 5-14 μJ/μm², for example. However, if the energy density is increased further, the silicon powder can be over-burnt, and the printed component can lose its geometry accuracy.

In the present disclosure, for printing silicon, the controller 1234 may set the energy density in a range between 10-14 μJ/μm², for example. The silicon powder fully melts and the printed silicon components are fully dense when the energy density is set in this range.

A plurality of layers (e.g., about fifty layers) of silicon, called buffer layers 1228, are initially printed on the steel substrate 1208. Each layer of the buffer layers 1228 is printed once and is printed quickly (i.e., with fast electron beam scanning). For example, the electron beam power may be set to 200 W, and the exposure time may be set to 50 μs. In this example, the corresponding energy density is only 2.1 μJ/μm². Due to the low energy density, some of the silicon powder may not fully melt. However, the purpose of the buffer layers 1228 is not to fully melt the silicon powder. Rather, as already explained above in detail, the buffer layers 1228 can avoid inconsistency of thermal expansion between the steel substrate 1208 and the lower layers of printed silicon component 1201 that are subsequently printed on top of the buffer layers 1228.

After printing the buffer layers 1228, the printing of the component 1201 begins. The component 1201 is printed on top of the buffer layers 1228 using double printing for each layer of the component 1201. For example, the electron beam power in the first printing of a layer (also called printing a first sublayer) may be set to 240 W (higher than that used to printer the buffer layers 1228), and the exposure time may be set to 50 μs (i.e., the first sublayer is also printed quickly; approximately similarly to the buffer layers 1228).

The second printing of the layer (also called printing the second sublayer) repeats the path of the first printing. The electron beam power and exposure time are increased (e.g., to 350 W and 150 μs) during the second printing. Accordingly, the energy density for printing the second sublayer is greater than the energy density for printing the first sublayer. For example, using the above examples of electron beam power and exposure times, the energy densities for the printing of the two sublayers of each layer may be 2.5 μJ/μm² and 11.0 μJ/μm² respectively.

The first printing (i.e., the printing of the first sublayer) melts some of the silicon powder in this layer and also defines the geometry of the component 1201. Then the second printing fully melts all of the silicon powder left un-melted in the first printing. The higher energy density in the second printing also elevates the temperature of the printed silicon component 1201 to a high level for slow cooling in the fast heating-cooling cycles in printing. The slow cooling of the currently printed layer serves a similar thermal purpose for subsequently printed layers as that served by the buffer layers 1228 for the currently printed layer.

The controller 1234 selects the energy density of the second printing such that the silicon powder fully melts and over-burning of the silicon powder is also avoided. This double printing method also protects the printed components from contamination due to spatter ejection of particles, thus avoiding pores induced by the spatter ejection, which is described below.

Spatter ejection occurs when bright (hot) particles of silicon (or the nonmetallic material 1210) are ejected away from the melting pool due to recoil pressure during printing of each layer. These particles cool down in flight and may land on the printed component. The landed spatter ejection particles are generally bigger than the size of the silicon powder and might not be fully melted during printing of the next layer. This can cause porosity problem and reduce the strength of the printed component.

Spatter ejection can be caused by high energy density and/or low printing speed. According to the present disclosure, the double printing method of printing a layer prints the first sublayer of the layer with a low energy density electron beam to define the geometry in first printing. Using vacuum instead of an inert gas flow in the vacuum chamber 1202 during printing significantly reduces spatter. The low energy density (e.g., 2.5 μJ/μm²) and high printing speed (e.g., 1300 mm/s) further reduces the intensity of spatter ejection. Most of the silicon powder is melted in this step and solidified around the un-melted silicon powders after the electron beam 1226 stops. This prevents the un-melted powder from spattering by the recoil pressure. Then the second printing (i.e., the printing of the second sublayer on top of the first sublayer) with a high energy density electron beam and slower printing speed than the first printing fully melts all the un-melted silicon powder, and the intensity of spatter ejection is substantially reduced. The double printing strategy effectively reduces the intensity of spatter ejection, which significantly minimizes or eliminates porosity problem caused by spatter ejection.

FIG. 11A shows a method 1300 for printing a component of a nonmetallic material on a metal substrate using buffer layers and double printing according to the present disclosure. FIG. 11B shows the double printing method 1350 in further detail. For example, the methods 1335 and 1350 are performed by the controller 1234.

In FIG. 11A, at 1336, the method 1335 filters or screens a stock of silicon powder manufactured using PREP by using one or more meshes and a vibration system (e.g., as shown in FIG. 10D). At 1338, the method 1335 prints a plurality of buffer layers of the nonmetallic material on the metal substrate prior to printing the component layers. At 1340, the method 1335 prints each component layer on top of the buffer layers using the double printing method 1350 shown in detail in FIG. 11B.

At 1342, the method 1335 determines if all the layers of the component are printed. At 1344, if all the layers of the component are not yet printed (i.e., if printing of the component is not yet completed), the method 1335 feeds the filtered or screened powder of the nonmetallic material to the powder bed to print the next layer of the component; and the method 1335 returns to 1340. At 1346, if all the layers of the component are printed (i.e., if printing of the component is completed), the method 1335 separates the printed component of the nonmetallic material from the metal substrate; and the method 1335 ends.

FIG. 11B shows the double printing method 1350 in further detail. At 1352, the method 1350 selects first and second angles for printing first and second sublayers of a layer of the component. At 1354, the method 1352 prints, in a first pass, the first sublayer of the layer of the component using a fast scanning, low-power electron beam oriented at the selected first angle. At 1356, the method 1352 prints, in a second pass, the second sublayer of the layer of the component using a slow scanning, high-power electron beam oriented at the selected second angle.

At 1358, the method 1350 determines if all the layers of the component are printed. At 1360, if all the layers of the component are not yet printed (i.e., if printing of the component is not yet completed), the method 1350 changes at least one of the first and second angles to be used for printing the next layer of the component; and the method 1350 returns to 1354. The method 1350 ends if all the layers of the component are printed (i.e., if printing of the component is completed).

Thus, the advantages of the system 1200 and the method 1335 according to the first solution of the present disclosure include the following. The powder of the nonmetallic material manufactured using PREP or ICTP has much higher quality as compared to the powders traditionally manufactured with gas atomization. The particles of the powder manufactured using PREP or ICTP are also highly spherical and have smooth surfaces. Accordingly, the flowability and spreadability of the powder made using PREP or ICTP are much better than those of the powder made using gas atomization or chemical vapor deposition or crash of silicon solid. Further, the diameter of the particles is controlled and selected using one or more meshes and vibration as explained above.

The metal (e.g., steel) substrate protects the printed silicon component from fracturing. Ideally, silicon substrate is the only or preferred candidate as the substrate material. However, silicon substrate can fracture when subjected to high thermal load (or high temperature gradient) during printing, and the cracks can propagate through the printed silicon component causing fracturing. Steel being a ductile material can withstand the high temperature gradient and does not fracture.

The buffer layers reduce the CTE mismatch between the steel substrate and the printed silicon (i.e., between metal substrate and nonmetallic layers of the component being printed on the metal substrate). Further, the first printing (i.e., printing the first sublayer of each layer of the component) defines the component geometry. Most of silicon powder is melted in the first printing. The dissipation of melting pool restrains the un-melted silicon powder surrounded by the melted silicon. Therefore, spatter ejection is substantially reduced together with fast printing speed in the first printing. This avoids pores or voids in the printed component that can be induced by spatter ejection. Then the second printing fully melts all the un-melted silicon powder and elevates the component temperature to a high level before the printing of the next layer starts.

FIGS. 12A-12C show a powder bed based system and method for 3D printing a component of a nonmetallic brittle material on a substrate of the same nonmetallic material according to the crack free printing method of the present disclosure. An electron beam generator is configured to supply an electron beam to print a layer of the nonmetallic material on the substrate while a heater continues to heat the substrate and a region of a chamber surrounding the substrate during the printing.

FIG. 12A shows a powder bed based system 1400 for 3D printing a component 1401 of a nonmetallic material on a substrate of the same nonmetallic material. The system 1400 comprises a vacuum chamber 1402. The vacuum chamber 1402 comprises a first plate 1404 and a second plate 1406. The first plate 1404 supports a substrate 1408 on which the component 1401 is printed. Accordingly, the first plate 1404 is also called a building plate, a building platform, a printing plate, or another suitable name.

The second plate 1406 stores the nonmetallic material 1410. A dose bar or a powder wiper 1412 supplies the nonmetallic material 1410 to the substrate 1408 prior to printing each layer. Accordingly, the second plate 1406 is also called a feeding plate, a dosing plate, or another suitable name.

The vacuum chamber 1402 comprises an observation window 1414. The observation window 1414 is coated with a film to reduce heat dissipation. The system 1400 further comprises an electron beam generator 1420, which generates an electron beam 1426 onto the substrate 1408 during printing. For example, the electron beam generator 1420 is similar to the electron beam generator 1170 shown in FIG. 9B. Accordingly, the electron beam generator 1420 is not described in detail for brevity.

The vacuum chamber 1402 is thermally insulated with an insulating material 1428. The insulating material 1428 is described below in further detail. A heater 1430 is used to heat the substrate 1408 before and during the printing of the component 1401. A layer of the insulating material 1428 is arranged between the top of the first plate 1404 and the bottom of the heater 1430. One or more heaters 1432 are used to heat the region surrounding the substrate 1408 during printing. A temperature sensor 1434 is used to sense the temperature of the region surrounding the substrate 1408. The heaters 1430, 1432 are controlled based on the sensed temperature.

FIG. 12B shows additional elements of the system 1400. The system 1400 further comprises a vacuum pump 1418 that is connected to the vacuum chamber 1402 via a valve 1416 to maintain a high vacuum in the vacuum chamber 1402. For example, the pressure in the vacuum chamber 1402 can be <1E-5 Torr, which is the same as <0.01 mTorr or <1.33 mPa. The system 1400 further comprises a plate movement assembly 1452 to move the first plate 1404 downwards and to move the second plate 1406 upwards during printing. The system 1400 further comprises a power supply and a temperature controller (shown as temperature/heater power controller 1456) to maintain the desired temperatures inside the hot zone. The system 1400 further comprises a controller 1454 that controls all the elements of the system 1400 as explained below.

Current 3D printing equipment is designed for printing metals which are ductile materials and are more tolerant to thermal stress. Therefore, ex-situ annealing can be used to reduce thermal stress. However, the current conventional 3D printing equipment is not capable of uniform heating and maintaining substrate temperatures greater than about 600° C. Accordingly, large temperature gradients can occur in the silicon component being printed in these machines since the melt pool temperature is greater than the melting point of silicon (1414° C.), and adjacent silicon (i.e., silicon adjacent to the melt pool) is likely at temperatures <700 C. In addition, in the current 3D printing equipment, the cool down is fast and not controlled. The large temperature gradient during printing and fast cooling down lead to micro-cracks in the 3D-printed silicon components using conventional 3D printers. The micro-cracks cannot be healed in ex-situ annealing.

Therefore, the system 1400 provides the 3D printing equipment with a low temperature gradient. The system 1400 uses one or multiple heaters 1430, 1432 along with thermal insulation (i.e., the insulating material 1428) to minimize the temperature gradient during printing, in-situ annealing, and cooling. The heaters 1430, 1432 can be either resistive or inductive heaters, infrared (IR) lamp radiation heaters, or blue light heaters (e.g., using blue LEDs). The insulating material 1428 can be either rigid carbon fiber insulation or soft graphite felt or combination of both. Due to high reactivity of carbon and melted silicon with oxygen at elevated temperatures during printing, the system 1400 needs to be vacuum tight.

In one embodiment, vacuum chamber 1402 is rectangular in shape with rigid insulation plates (i.e., rigid plates of the insulating material 1428) covering the inside at top and bottom, left and right, front and back. In another embodiment, the vacuum chamber 1402 is cylindrical in shape with rigid insulation plates covering the inside at top and bottom and rigid insulation cylinder shielding the surrounding cylindrical wall. Other shapes are contemplated.

The insulation plate or cylinder can be made of multiple layers, such as rigid insulation/rigid insulation, graphite/rigid insulation, rigid insulation/felt, graphite/felt, carbon fiber composite (CFC)/felt. Felt is essentially a cloth-like soft material made of many layers of carbon fiber. Insulation prevents heat from escaping and helps in maintaining the high temperature uniformly throughout the printing process (i.e., insulation and heaters help in maintaining a low thermal gradient throughout the printing process).

For 3D printing of silicon, graphite resistive heaters are preferred. A graphite susceptor (i.e., a shield, not shown) can be placed inside the side heater 1432 to protect the heater 1432. The silicon powder is selected as described in the fully dense printing method, and the selection process is therefore not repeated for brevity. The silicon powder is dosed by the powder wiper 1412 after completion of printing of each layer. When the printing of all layers is completed, the printed component 1401 is embedded in silicon powder. The silicon powder can also prevent heat from dissipating in the horizontal direction. The silicon powder has low thermal conductivity and slightly slows cooling of the printed component.

Due to the brittle nature of silicon, the substrate temperature for 3D printing is preferred to be greater than the ductile to brittle transition temperature or DBTT of silicon (i.e., greater than 1000° C.) during printing and annealing of the printed component 1401 to prevent thermal stress buildup. For example, the annealing temperatures are preferred to be between 1100-1200° C. It is also preferred to cool down the printed component 1401 slowly at a controlled rate. For example, the cool down is preferred to be at a rate of less than 5° C./min from the annealing temperature to about 400° C., and is followed by backfill of an inert gas (e.g., Ar). The substrate 1408 for 3D printing of the component 1401 of silicon is preferably made of silicon to avoid CTE mismatch between the substrate 1408 and the component 1401 and contamination from substrates made of other materials. The concept can be applied to other brittle materials such as alumina, silicon carbide, ceramics, etc.

FIG. 12C shows a powder bed based method 1480 for 3D printing a component (e.g., element 1401) of a nonmetallic material on a substrate (e.g., element 1408) of the same nonmetallic material according to the second solution of the present disclosure. For example, the method 1480 is performed by the controller 1454.

At 1482, the method 1480 creates vacuum in a thermally insulated chamber. At 1484, before starting the printing of the component 1401, the method 1480 heats the substrate 1408 and a region proximate to the printing area (i.e., surrounding the substrate 1408) using one or more heaters (e.g., heaters 1430, 1432).

At 1486, the method 1480 feeds filtered or screened silicon powder to form a powder bed on the substrate 1408. The method 1480 supplies an electron beam 1426 to print a layer of the silicon powder while maintaining the heat provided by the one or more heaters 1430, 1432. The method 1480 senses the temperature in the vacuum chamber 1402 (e.g., of the region surrounding the substrate) and maintains the temperature of the substrate 1408 and the surrounding region to a temperature greater than the DBTT of the silicon (or the nonmetallic material being used to print the component).

At 1488, the method 1480 determines if all the layers of the component 1401 are printed (i.e., if the printing of the component is completed). The method 1480 returns to 1486 if all the layers of the component 1401 are not yet printed (i.e., if the printing of the component is not yet completed).

At 1490, the method 1480 anneals the printed component 1401 while maintaining the heat supplied by the heaters 1430, 1432 under the control of the controller 1454. At 1492, under the control of the controller 1454, the method 1480 controls the annealing and the cooling of the printed component 1401 using the heaters 1430, 1432, the insulation 1428, and using the silicon powder surrounding the printed component, and the method 1480 ends.

Thus, the system 1400 and method 1480 according to the crack free printing method includes adding heaters and thermal insulation to the metal 3D-printing equipment, which enables maintaining a lower temperature gradient during printing and in-situ annealing as well as slower cool down at a controlled cooling rate, which significantly reduces thermal stress in the printed silicon component and eliminates micro-cracks.

The conventional metal 3D printing equipment is not capable of maintaining temperatures above 600° C. and controlled cool down, which induces high thermal stress and causes micro-cracks in the printed silicon component and renders it useless. The solution also uses vacuum tight chamber to prevent oxidation of melted silicon, graphite based heaters, and carbon fiber based thermal insulations. The conventional metal 3D printing equipment does not require vacuum tight.

FIGS. 13A-15B show systems and methods for bonding and repairing silicon components used in processing chambers and semiconductor processing tools. Throughout the following description, silicon components are used for example only. The following teachings can be used with components made from any nonmetallic material selected from a group consisting of silicon, silicon carbide, alumina, and ceramics.

For example, a component such as a C-shaped shroud used in a processing chamber may be typically manufactured as a monolithic component. However, monolithic components are difficult to manufacture. Instead, it can be easier to manufacture a plurality of subcomponents of a component and then bond them to form a single component as described below.

Additionally, silicon components used in substrate processing systems may get chipped during manufacturing process or their use in processing chambers. It is expensive to discard and replace a component due to minor chipping. Instead, the chipped component can be repaired as described below so that the repaired component can be used instead of discarding and replacing the chipped component. The repair can lengthen the useful life of the component or reduce the scrap rate of manufacturing the component.

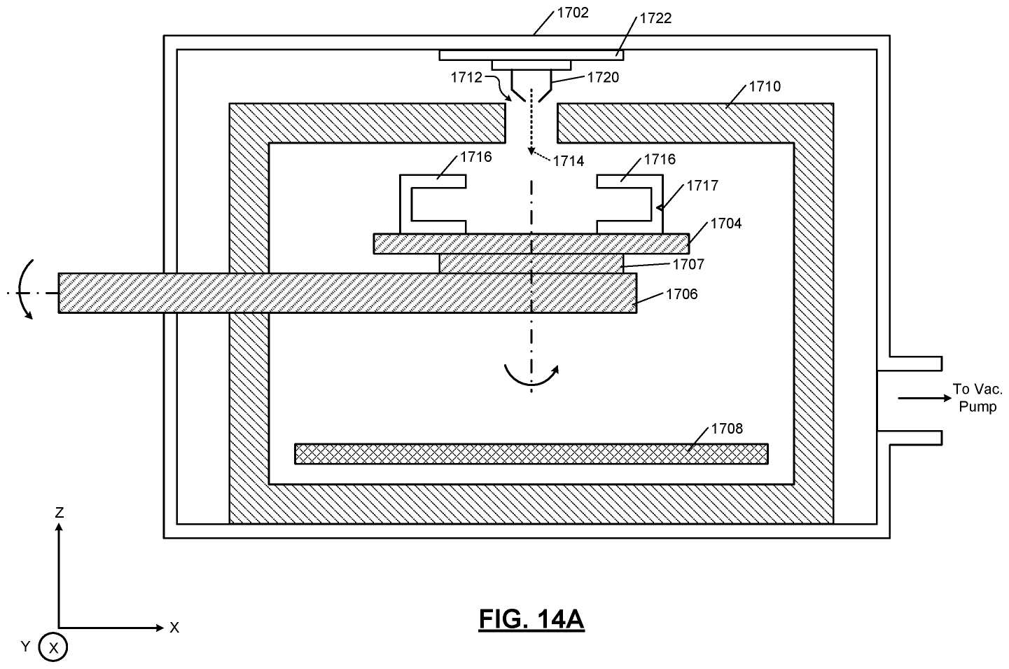

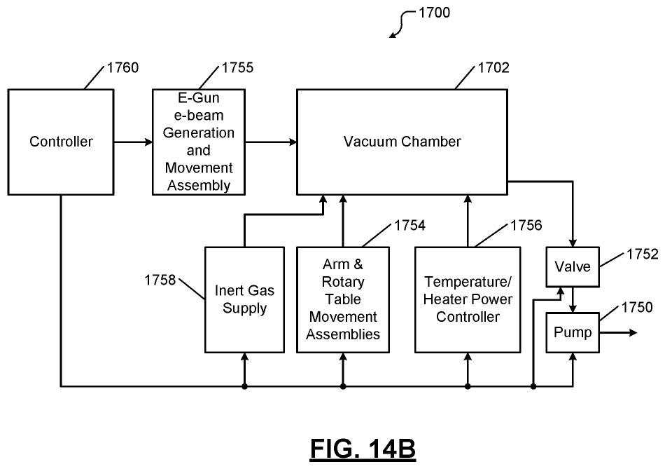

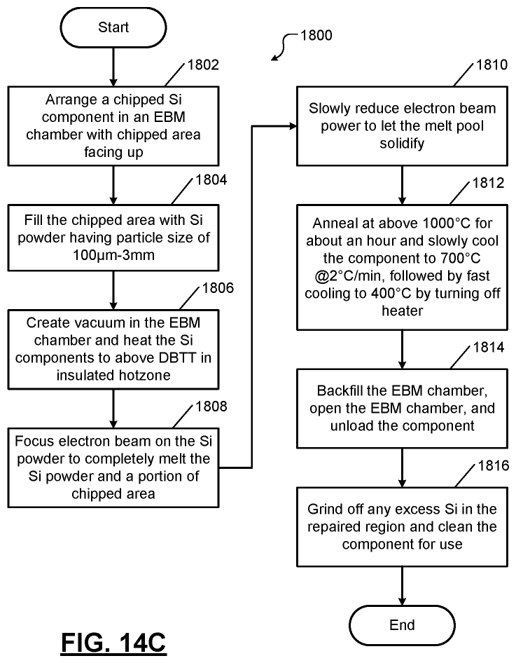

FIGS. 13A-13C show a system and a method for bonding silicon components. FIGS. 14A-14C show a system and a method for repairing silicon components. FIGS. 15A and 15B show a combined system for bonding and repairing silicon components in a single chamber. Again, silicon components are used for example only, and the systems and methods can be used with components made of any nonmetallic material such as silicon, silicon carbide, alumina, and ceramics.

FIG. 13A shows a vacuum chamber 1502 of a system 1500 for bonding silicon components. The complete system 1500 is shown in detail in FIG. 13B. In FIG. 13A, the vacuum chamber 1502 of the system 1500 is shown in detail. The walls of the vacuum chamber 1502 are made of stainless steel. While not shown, the walls of the vacuum chamber 1502 are cooled by circulating a coolant such as water through the walls.

The vacuum chamber 1502 encloses a pedestal 1504. The pedestal 1504 supports a susceptor 1506. The pedestal 1504 and the susceptor 1506 can be rotated around Z axis. A heater 1508 is arranged around the pedestal 1504. The heater 1508 can be arranged under the susceptor 1506 as shown. Alternatively, while not shown, the heater 1508 can be arranged on the sides of (i.e., around) the susceptor 1506 and the pedestal 1504. The pedestal 1504, the susceptor 1506, and the heater 1508 are made of graphite.

A thermal insulation 1510 is disposed in the vacuum chamber 1502 around the pedestal 1504, the susceptor 1506, and the heater 1508. The thermal insulation 1510 is made of rigid carbon fiber. Alternatively, the thermal insulation 1510 can include graphite wrapped with felt. The thermal insulation 1510 forms an insulated hot zone in the vacuum chamber 1502 around the pedestal 1504, the susceptor 1506, and the heater 1508.

An electron gun 1520 is mounted to a sidewall of the vacuum chamber 1502 using a fixture 1522. The electron gun 1520 is movable along Z axis. A component 1516 comprising a plurality of elements (i.e., subcomponents or pieces) is arranged on the susceptor 1506. For example only, the component 1516 may include three elements 1516-1, 1516-2, and 1516-3. The thermal insulation 1510 includes a slot 1512 through which an electron beam 1514 from the electron gun 1520 can irradiate the elements of the component 1516. By moving the electron gun 1520 and rotating the pedestal 1504, different portions of the elements of the component 1516 can be irradiated. In some examples, the pedestal 1504 may also be movable vertically along Z axis.

The electron beam 1514 bonds the elements 1516-1, 1516-2, and 1516-3 to form the component 1516 using a method described below with reference to FIG. 13C. For example, the electron beam 1514 bonds the element 1516-1 to the element 1516-2 at 1517, and the electron beam 1514 bonds the element 1516-2 to the element 1516-3 at 1518 using the method described below with reference to FIG. 13C. Before describing the method, the remainder of the system 1500 is described below with reference to FIG. 13B.

In FIG. 13B, the system 1500 comprises a vacuum pump 1550 that is connected to the vacuum chamber 1502 via a valve 1552 to maintain a high vacuum in the vacuum chamber 1502. For example, the pressure in the vacuum chamber 1502 can be <1E-5 Torr, which is the same as <0.01 mTorr or <1.33 mPa. The system 1500 further comprises a pedestal movement assembly 1554 to rotate the pedestal 1504. The system 1500 further comprises an electron gun e-beam generation and movement assembly 1555 to move the electron gun 1520.

The system 1500 further comprises a power supply and a temperature controller (collectively shown as temperature/heater power controller 1556) to maintain desired temperatures inside the hot zone (described below with reference to FIG. 13C). The system 1500 further comprises an inert gas supply 1558 to supply an inert gas such as argon (Ar) to backfill the vacuum chamber 1502. The system 1500 further comprises a controller 1560 that controls all the elements of the system 1500 as explained below with reference to FIG. 13C.

FIG. 13C shows a method 1600 for bonding silicon components. For example, the controller 1560 performs the method 1600 by controlling the various elements of the system 1500 as follows. At 1602, the method 1600 includes cleaning the mating surfaces of the elements that are to be bonded to form a component (e.g., cleaning the mating surfaces of the elements 1516-1, 1516-2, and 1516-3 at 1517 and 1518 to form the component 1516). At 1604, the method 1600 includes arranging the elements of the component in a 3D electron beam printer or welder (e.g., on the susceptor 1506 in the vacuum chamber 1502). No silicon powder is added between the mating surfaces of the elements to be bonded together (e.g., no silicon powder is added at 1517 and 1518).

At 1606, the method 1600 includes operating the pump 1550 to create vacuum in the vacuum chamber 1502 as described above with reference to FIGS. 13A and 13B. Additionally, the method 1600 includes operating the heater 1508 using the temperature/heater power controller 1556 to heat the elements of the component to above brittle to ductile transition point of silicon (>800° C.) in the insulated hot zone, which is created in the vacuum chamber 1502 using the thermal insulation 1510 as described above with reference to FIGS. 13A and 13B.

At 1608, the method 1600 includes focusing the electron beam 1514 of the electron gun 1520 to a first area of a joint (e.g., 1517) between two elements (e.g., 1516-1 and 1516-2) until the silicon at the first area (i.e., silicon at portions of extremities of the two elements) melts and solidifies. The method 1600 may include slowly reducing the power of the electron beam 1514 to let the melt pool solidify at the last portion of a joint.

At 1610, the method 1600 includes determining if all the areas of the joint (i.e., the entirety of 1517) are melted and solidified. If all the areas of the joint are not melted and solidified, the method 1600 proceeds to 1612. At 1612, the method 1600 includes slowly rotating the component (by rotating the pedestal 1502 using the pedestal movement assembly 1554) to select a next area of the selected joint for melting and solidification, after which the method 1600 returns to 1608. The method 1600 can also include moving the electron gun 1520 using the electron gun movement assembly 1555 to irradiate different areas of a joint. If all the areas of the joint are melted and solidified, the method 1600 proceeds to 1614.

At 1614, the method 1600 includes determining if all the joints (e.g., 1517 and 1518) of the component are melted and solidified (i.e., if all the elements of the component are joined or welded together to form the component). If all the joints of the component are not melted and solidified, the method 1600 proceeds to 1616. At 1616, the method 1600 includes selecting the next joint (e.g., 1518) to be melted and solidified, after which the method 1600 returns to 1608. For example, the method 1600 includes selecting the next joint by rotating the pedestal 1504 using the pedestal movement assembly 1554. If all the joints are melted and solidified, the bonding of the elements to form the component (hereinafter the bonded component) is complete, and the method 1600 proceeds to 1618.

At 1618, the method 1600 includes annealing the joints of the bonded component. For example, the method 1600 includes controlling the heater 1508 using the temperature/heater power controller 1556 to heat the bonded component and hold the temperature at above 1000° C. for about an hour. Then the method 1600 includes slowly cooling the bonded component to about 700° C. at a rate of about <2 C/min, which is followed by a faster cooling of the bonded component to about 400° C. by powering off the heater 1508.

At 1620, the method 1600 includes backfilling the vacuum chamber 1502 with an inert gas such as argon (Ar) supplied by the inert gas supply 1558. The method 1600 then includes opening of the vacuum chamber 1502 and unloading of the bonded component from the vacuum chamber 1502. At 1622, the method 1600 includes grinding off any excess silicon from the bonded component and re-cleaning the bonded component for use in a processing chamber or a substrate processing system such as that shown in FIG. 9A.

FIG. 14A shows a vacuum chamber 1702 of a system 1700 for repairing silicon components. The complete system 1700 is shown in detail in FIG. 14B. In FIG. 14A, the vacuum chamber 1702 of the system 1700 is shown in detail. The walls of the vacuum chamber 1702 are made of stainless steel. While not shown, the walls of the vacuum chamber 1702 are cooled by circulating a coolant such as water through the walls.

The vacuum chamber 1702 encloses a rotary table 1704. A component 1716 to be repaired is arranged on the rotary table 1704. For example, the component 1716 may include a chipped region 1717 that needs to be repaired. The rotary table 1704 is rotatable around Z axis. The rotary table 1704 is mounted to an arm 1706 using a fixture 1707. The arm 1706 is rotatable around X axis. Thus, the rotary table 1704 is rotatable around Z and X axes. In some examples, the arm 1706 together with the rotary table 1704 may also be movable along X axis. The rotary table 1704 and the arm 1706 are made of graphite. A distal end of the arm 1706 may be extended and supported by a supporting structure (not shown) if the component 1716 and/or the rotary table 1704 are relatively heavy.

A heater 1708 is arranged under the rotary table 1704 and the arm 1706. Alternatively, while not shown, the heater 1708 can be arranged along the sidewalls of the vacuum chamber 1702 around the rotary table 1704 and the arm 1706. A thermal insulation 1710 is disposed in the vacuum chamber 1702 around the rotary table 1704, the arm 1706, and the heater 1708. The thermal insulation 1710 is made of rigid carbon fiber. Alternatively, the thermal insulation 1710 can include graphite wrapped with felt. The thermal insulation 1710 forms an insulated hot zone in the vacuum chamber 1702 around the rotary table 1704, the arm 1706, and the heater 1708.

An electron gun 1720 is mounted to a top wall of the vacuum chamber 1702 using a fixture 1722. The electron gun 1720 is movable along X and Y axes. The thermal insulation 1710 includes a slot 1712 through which an electron beam 1714 from the electron gun 1720 can irradiate the chipped region 1717 of the component 1716. By moving the electron gun 1720 and rotating the rotary table 1704 and the arm 1706, different portions of the component 1716 can be irradiated.

Specifically, the rotary table 1704 can not only rotate around its own axis (Z axis) perpendicular to its plane but can also be rotated around the axis parallel to its plane (X axis) by rotating the arm 1706. These two rotations allow moving the chipped region 1717 to the top so as to face the electron gun 1720. By moving the electron gun 1720 along X and Y axes, the electron beam 1714 can be directed to the chipped region 1717. To repair, the chipped region 1717 is filled with silicon powder, which the electron beam 1714 melts using a method described below with reference to FIG. 14C. Before describing the method, the remainder of the system 1500 is described below with reference to FIG. 14B.

In FIG. 14B, the system 1700 comprises a vacuum pump 1750 that is connected to the vacuum chamber 1702 via a valve 1752 to maintain a high vacuum in the vacuum chamber 1702. For example, the pressure in the vacuum chamber 1702 can be <1E-5 Torr, which is the same as <0.01 mTorr or <1.33 mPa. The system 1700 further comprises movement assemblies to rotate the rotary table 1704 and the arm 1706, which are collectively shown as arm and rotary table movement assemblies 1754. The system 1700 further comprises an electron gun e-beam generation and movement assembly 1755 to move the electron gun 1720.

The system 1700 further comprises a power supply and a temperature controller (collectively shown as temperature/heater power controller 1756) to maintain desired temperatures inside the hot zone (described below with reference to FIG. 14C). The system 1700 further comprises an inert gas supply 1758 to supply an inert gas such as argon (Ar) to backfill the vacuum chamber 1702. The system 1700 further comprises a controller 1760 that controls all the elements of the system 1700 as explained below with reference to FIG. 14C.

FIG. 14C shows a method 1800 for repairing silicon components. For example, the controller 1760 performs the method 1800 by controlling the various elements of the system 1700 as follows. At 1802, the method 1800 includes arranging a chipped component (e.g., the component 1715 with the chipped region 1717) in an EBM chamber (e.g., the vacuum chamber 1702). The method 1800 includes rotating the rotary table 1704 and the arm 1706 using the arm and rotary table movement assemblies 1754 so that the chipped region 1717 is facing up towards the electron gun 1720.

At 1804, the method 1800 includes filling the chipped region 1717 with silicon powder (e.g., including particles having a diameter in the range 100 um-3 mm and the same resistivity as the component 1715). At 1806, the method 1800 includes operating the pump 1750 to create vacuum in the vacuum chamber 1702 as described above with reference to FIGS. 14A and 14B. Additionally, the method 1800 includes operating the heater 1708 using the temperature/heater power controller 1756 to heat the component to above brittle to ductile transition point of silicon (>800° C.) in the insulated hot zone, which is created in the vacuum chamber 1702 using the thermal insulation 1710 as described above with reference to FIGS. 14A and 14B.

At 1808, the method 1800 includes focusing the electron beam 1714 of the electron gun 1720 on the silicon powder in the chipped region 1717 of the component to completely melt the silicon powder and a portion of the chipped region 1717. The method 1800 may also include moving the electron gun 1720 using the electron gun movement assembly 1755. At 1810, the method 1800 includes slowly reducing the electron beam power to let the melt pool in the chipped region 1717 solidify.

At 1812, the method 1800 includes annealing the repaired component. For example, the method 1800 includes controlling the heater 1708 using the temperature/heater power controller 1756 to heat the repaired component and hold the temperature at above 1000° C. for about an hour. Then the method 1800 includes slowly cooling the repaired component to about 700° C. at a rate of about ≤2 C/min, which is followed by a faster cooling of the repaired component to about 400° C. by turning off the heater 1708.

At 1814, the method 1800 includes backfilling the vacuum chamber 1702 with an inert gas such as argon (Ar) supplied by the inert gas supply 1758. The method 1800 then includes opening of the vacuum chamber 1702 and unloading of the repaired component from the vacuum chamber 1702. At 1816, the method 1800 includes grinding off any excess silicon from the repaired region and re-cleaning the repaired component for use in a processing chamber or a substrate processing system such as that shown in FIG. 9A.

FIG. 15A shows a system 1900 for bonding and repairing silicon components in a single vacuum chamber 1902. Essentially, the system 1900 is a combination of the systems 1500 and 1700 since both bonding and repairs can be performed in a single vacuum chamber 1902. The vacuum chamber 1902 includes all of the elements of the vacuum chamber 1702 and further includes the following elements of the vacuum chamber 1502: the slot 1512 is added to the thermal insulation 1710, and the electron gun 1520 is mounted to the sidewall of the vacuum chamber 1902 using the fixture 1522.

Otherwise, the vacuum chamber 1902 is identical to the vacuum chamber 1702 and is therefore not described again for brevity.

In the vacuum chamber 1902, the elements 1516-1, 1516-2, 1516-3 of the component 1516 can be arranged on the rotary table 1704 and can be bonded using the electron gun 1520 as described above with reference to FIGS. 13A-13C. Further, the chipped region 1717 on the component 1716 can be repaired using the electron gun 1720 as described above with reference to FIGS. 14A-14C.

FIG. 15B shows additional elements of the system 1900. The system 1900 includes all of the elements of the system 1700 shown in FIG. 14B and further includes the electron gun movement assembly 1555 of the system 1500. A controller 1954 includes the functionalities of the controllers 1554 and 1754. The controller 1954 can perform the methods 1600 and 1800 described above, which are not described again for brevity.

In some examples, the system 1700 can also be used (repurposed) to bond pieces of a component as described with reference to FIGS. 13A-13C. In other examples, two robot arms can be provided in the system 1400, which can then be used to bond as well as repair component. For example, in a bonding application, the two robot arms can be used to hold two pieces of a component. The two robot arms can be moved with appropriate degrees of freedom such that the electron gun can bond the two pieces to form the component. In a repair application, one or both robot arms can be used to hold the component to be repaired. Then one or both robot arms can be with appropriate degrees of freedom such that the electron gun can melt the powder in the defective region of component to repair the component. In still other examples, in the system 1900, both electron guns can be used to bond elements of a component, and both electron guns can be used to repair multiple chips on a defective component. Many other variations and uses of the various systems and methods described herein are contemplated.

FIGS. 16A-16C show bonding of two silicon components using the systems and methods of FIGS. 13A-13C, 15A, and 15B resulting in a grain boundary between the two components due mismatched crystalline orientation. For example, a silicon component 2000 is formed by bonding two silicon subcomponents 2002 and 2004 respectively shown as Subcomponent 1 and Subcomponent 2. FIG. 16A shows the subcomponents 2002, 2004 before bonding. FIG. 16B shows the subcomponents 2002, 2004 during bonding. FIG. 16C shows the silicon component 2000 after the bonding of the subcomponents 2002, 2004.

In FIG. 16A, each of the first and second subcomponents 2002, 2004 has a single crystalline structure. The first and second subcomponents 2002, 2004 respectively have edges 2006, 2008 at which the two subcomponents 2002, 2004 are to be bonded.

The edges 2006, 2008 are also called welding surfaces. In a single-crystal or monocrystalline material such as the first and second subcomponents 2002 and 2004, a crystal lattice of the entire individual subcomponent is continuous and unbroken to the edges with no grain boundaries. A grain boundary is an interface between two grains or crystallites in a polycrystalline material. The edges 2006, 2008 of the two subcomponents 2002 and 2004 comprise crystals with two different crystalline orientations. When bonding the two subcomponents 2002 and 2004, it is impossible to exactly align their crystalline orientations in atomic scale. The two subcomponents 2002 and 2004 are bonded at the edges 2006, 2008 by applying the electron beam 1514 at the edges 2006, 2008 as described with reference to FIGS. 13A-13C, 15A, and 15B.

In FIG. 16B, a molten zone 2010 is formed at the edges 2006, 2008 of the subcomponents 2002 and 2004 when the electron beam 1514 irradiates at the edges 2006, 2008. The molten zone 2010 is allowed to solidify, annealed, and allowed to cool as described with reference to FIGS. 13A-13C, 15A, and 15B.

In FIG. 16C, the bonded the subcomponents 2002 and 2004 form the component 2000. A gain boundary 2012 is formed at the bond (i.e., in the bonded region or the joint) between the subcomponents 2002 and 2004 due to their inevitable crystalline orientation mismatch. The grain boundary 2012 is the seam of solidification of the melted material from the subcomponents 2002 and 2004 at the joint between the subcomponents 2002 and 2004. The grain boundary 2012 can also be called the seam of the solidification from the subcomponents 2002 and 2004.

The grain boundary 2012 is also formed if the subcomponents 2002 and 2004 are made of multi-crystalline silicon since each grain in the multi-crystalline silicon is a small single crystal. At the joint between the subcomponents 2002 and 2004 made of multi-crystalline silicon, a plurality of the grain boundary 2012 will be formed between each pair of two grains facing each other during solidification. The grain boundary 2012 will also be formed if a laser beam is used to melt the edges 2006, 2008 to join the subcomponents 2002, 2004 to form the component 2000. The plurality of grain boundaries 2012 will also be formed if the joint between the edges 2006, 2008 is filled with silicon powder and melted by the electron beam or the laser beam to form the component 2000.

The grain boundary 2012 is a detectable feature of the bonded component 2000. For example, if the component 2000 were monolithic (i.e., manufactured as a single piece and not manufactured by bonding two subcomponents), the component 2000 will not include the grain boundary 2012. Further, if the subcomponents 2002 and 2004 are joined to form the component 2000 using a process other than the processes described with reference to FIGS. 13A-13C, 15A, and 15B, the component 2000 will not include the grain boundary 2012 at the joint between the subcomponents 2002 and 2004.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

The program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1. A method of performing three-dimensional (3D) printing of a silicon component, the method comprising:
adding powdered silicon to a 3D printing tool;
for each layer of the 3D printing in a layer-by-layer process:
forming a powder bed of the powdered silicon in the 3D printing tool;
baking the powdered silicon in a temperature range of 650° C. to 750° C. under a high-vacuum condition in a range of 10-5 Torr to 10-7 Torr to decompose and remove surface oxides from the powdered silicon;
forming a layer of the powder bed to a pre-determined thickness;
directing a high-powered beam under the high-vacuum condition in a pre-determined pattern into the formed powder-bed, the high-powered beam having sufficient energy to melt the powdered silicon; and
making a determination as to whether additional layers in the 3D printing are needed; and
based on a determination that no additional layers are needed, cooling the silicon component at a pre-determined temperature ramp-down rate to ambient temperature of an environment in which the 3D printing tool is located.

2. The method of claim 1, wherein the high-powered beam comprises an electron beam.

3. The method of claim 1, wherein the method is performed within an inert gas environment.

4. The method of claim 3, wherein the inert gas environment comprises at least one gas selected from gases including argon (Ar) and helium (He).

5. The method of claim 1, wherein silicon particles in the silicon powder have a median size in a range of 45 μm to 55 μm and a distribution range of sizes between 10 μm to 100 μm.

6. The method of claim 1, wherein a purity of the powdered silicon is generally greater than 99.99%.

7. The method of claim 1, wherein a purity of the powdered silicon is generally greater than 99.9999%.

8. The method of claim 1, wherein the powdered silicon is baked in a temperature range of 700° C. under a high-vacuum condition in a range of 10-6 Torr to decompose and remove surface oxides from the powdered silicon.

9. The method of claim 1, wherein the powdered silicon comprises substantially spherical particles.

10. The method of claim 1, wherein the powdered silicon is formed by a fluidized-bed chemical vapor deposition (FB-CVD) system using silane (SiH₄)-gas atomization.

11. The method of claim 10, further comprising:
preparing molten silicon;
forcing the molten silicon through a nozzle;
directing a high-velocity gas stream at the molten silicon, the high-velocity gas stream comprising at least one gas selected from gases including helium (He) and argon (Ar) to break the molten silicon into silicon particles to form the powdered silicon; and
depositing silane on the silicon particles.

12. The method of claim 1, wherein the powdered silicon is formed by plasma rotation electrode processing (PREP).

13. The method of claim 12, further comprising:
melting an end of a silicon rod while the silicon rod is rotated, a rotational speed of the silicon rod being sufficient to create a centrifugal force to eject molten silicon from the silicon rod; and
solidifying the ejected molten silicon into silicon particles to from the powdered silicon.

14. The method of claim 13, further comprising adjusting a morphology of the silicon particles by adjusting the rotational speed of the silicon rod.

15. The method of claim 1, wherein the pre-determined temperature ramp-down rate is less than 5° C. per minute.

16. The method of claim 1, further comprising:
preparing high-purity silicon by operations including:
placing silicon into a crucible;
increasing a temperature of the silicon at a pre-determined ramp-up rate;
at least partially melting the silicon with high-powered beam, the high-powered beam having a power sufficient to melt the silicon; and
decreasing the temperature of the silicon at a second pre-determined ramp-down rate.

17. The method of claim 16, wherein the pre-determined ramp-up rate of temperature is determined by finite-element analysis including comparing heat flux and induced mechanical stresses in the silicon.

18. The method of claim 16, wherein the temperature ramp-rate is 50 K per minute.

19. The method of claim 16, wherein the pre-determined thickness of each layer in the layer-by-layer process is within a range from 30 μm to 50 μm.

20-29. (canceled)

30. A system for printing a fully dense component of a nonmetallic material, the system comprising:
a chamber under vacuum;
a first vertically movable plate arranged in the chamber to support a substrate;
a second vertically movable plate arranged adjacent to the first vertically movable plate, wherein the second vertically movable plate is configured to store a powder of the nonmetallic material and to dose the substrate with the powder prior to printing each layer of the nonmetallic material;
an electron beam generator configured to supply an electron beam; and
a controller configured to print a plurality of layers of the nonmetallic material on the substrate using the electron beam and to print a layer of the nonmetallic material on the plurality of layers to build the component on the plurality of layers.

31. The system of claim 30 wherein the nonmetallic material comprises spherical particles having a diameter within a range of 40-100 μm and wherein the diameter is measured using sieve analysis.

32. (canceled)

33. The system of claim 30 wherein the nonmetallic material is selected from a group consisting of silicon, silicon carbide, alumina, and ceramics.

34. The system of claim 30 further comprising:
one or more meshes having holes of different diameters; and
a vibrating system configured to vibrate the one or more meshes;
wherein the powder is selected from a stock by passing the stock through the one or more meshes; and
wherein the selected powder comprises particles having a diameter within a range of 40-100 μm which is measured using sieve analysis.

35. The system of claim 30 further comprising a plate movement assembly configured to move the first vertically movable plate in a downward direction after printing each layer and to move the second vertically movable plate in an upward direction after printing each layer.

36-73. (canceled)

74. A method of printing a fully dense and crack free component of a nonmetallic material on a substrate made of the nonmetallic material in a chamber, the method comprising:
heating the substrate and a region of the chamber surrounding the substrate prior to printing a layer of the nonmetallic material on the substrate; and
printing the layer of the nonmetallic material on the substrate using an electron beam while continuing to heat the substrate and the region of the chamber surrounding the substrate during the printing.

75. The method of claim 74 wherein the nonmetallic material comprises particles having a diameter within a range of 40-100 μm, and wherein the diameter is measured using sieve analysis.

76. The method of claim 74 further comprising heating the substrate and the region of the chamber surrounding the substrate to a temperature greater than a ductile to brittle transition temperature of the nonmetallic material during the printing and annealing of the component.

77. The method of claim 74 further comprising after the printing, annealing and slow cooling the component in the chamber while continuing to heat the substrate and the region of the chamber surrounding the substrate.

78. The method of claim 74 further comprising after the printing, cooling the component by surrounding the component with a powder of the nonmetallic material.

79. The method of claim 74 further comprising thermally insulating the chamber using one or more of layers of one or more insulating materials.

80. The method of claim 74 wherein the nonmetallic material is selected from a group consisting of silicon, silicon carbide, alumina, and ceramics.

81. The method of claim 74 further comprising:
dosing the substrate with the nonmetallic material prior to printing each layer of the layer of the nonmetallic material; and
supplying the electron beam subsequent to the dosing to print each layer of the nonmetallic material.

82. The method of claim 74 further comprising heating a region of the chamber above the substrate during the printing of the component.

83. The method of claim 74 further comprising maintaining vacuum in the chamber.

84. The method of claim 74 further comprising maintaining a vacuum in the chamber.

85. The method of claim 74 further comprising:
selecting a powder of the nonmetallic material from a stock by passing the stock through one or more meshes having holes of different diameters and by vibrating the one or more meshes,
wherein the selected powder comprises particles having a diameter within a range of 40-100 μm, and wherein the diameter is measured using sieve analysis.

86. A component of a nonmetallic material printed using the method of claim 74 wherein the component is fully dense and lacking porosity and cracking.

87. A system comprising:
a chamber including:
an upper portion having an inlet to receive silicon powder, a carrier gas, and a dopant;
a middle portion connected to the upper portion; and
a third portion connected to the middle portion and having an outlet;
a coil arranged around the upper portion;
a power supply configured to supply power to the coil; and
a controller configured to:
control supply of the silicon powder, the carrier gas, and the dopant to the inlet; and
control the power supplied to the coil to generate plasma,
wherein the outlet outputs a spherical shaped, dense, and doped silicon powder.

88. The system of claim 87 wherein the middle portion has a greater cross-sectional area than the upper portion and wherein the third portion has a smaller cross-sectional area than the upper portion.

89. The system of claim 87 wherein the upper portion includes:
an inner tube;
a middle tube coaxially surrounding the inner tube; and
an outer tube defined by an outer wall of the middle tube and an inner wall of the upper portion;
wherein the inner, middle, and the outer tubes extend vertically downwards from a top end of the upper portion to a midpoint of the upper portion; and
wherein the coil is arranged around the upper portion between the midpoint of the upper portion and a bottom end of the upper portion.

90. The system of claim 89 wherein the silicon powder is supplied to the inner tube, the system further comprising:
a first gas source to supply the carrier gas to mix with the silicon powder;
a second gas source to supply the dopant to the middle tube; and
a third gas source to supply a sheath gas to the outer tube.

91. A method of building a component for a substrate processing system, the method comprising:
arranging first and second subcomponents of the component in a thermally insulated zone in a chamber under vacuum;
heating the first and second subcomponents in the thermally insulated zone to a predetermined temperature;
bonding a first end of the first subcomponent to a second end of the second subcomponent by partially melting material at the first and second ends using an electron beam followed by solidifying the melted material;
annealing the bonded first and second subcomponents to form the component;
cooling the formed component to a first temperature at a first rate; and
cooling the formed component to a second temperature at a second rate,
wherein the second temperature is less than the first temperature; and
wherein the first rate is slower than the second rate.

92. The method of claim 91 wherein the component is made of a nonmetallic material selected from a group consisting of silicon, silicon carbide, alumina, and ceramics.

93. The method of claim 91 further comprising bonding the first and second subcomponents without using any additional material.

94. The method of claim 91 further comprising cleaning mating surfaces of the first and second ends before the melting.

95. The method of claim 91 further comprising grinding excess material from the component and cleaning the component.

96-125. (canceled)
